(19) United States
(12) Patent Application Publication
(10) Pub. No.: US 2025/0254892 A1
(43) Pub. Date: Aug. 7, 2025

(54) SEMICONDUCTOR DEVICE

(71) Applicant: Samsung Electronics Co., Ltd., Suwon-si (KR)

(72) Inventors: DONGHAK SHIN, Suwon-si (KR); ChangSik Yoo, Suwon-si (KR); JEONGDON IHM, Suwon-si (KR); YOUNG SEOK PARK, Suwon-si (KR); HYUN-CHUL YOON, Suwon-si (KR)

(21) Appl. No.: 18/779,418

(22) Filed: Jul. 22, 2024

(30) Foreign Application Priority Data
Feb. 5, 2024 (KR) 10-2024-0017688

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2225/06513; H01L 2225/06541; H01L 2225/06586; H01L 2924/1431; H01L 2924/1436

(57) ABSTRACT

A semiconductor device includes: a package substrate; and semiconductor chips stacked on the package substrate, wherein each of the semiconductor chips respectively includes a semiconductor substrate, a peripheral circuit structure and a cell array structure disposed to overlap each other in a vertical direction on the semiconductor substrate, a first contact pad in the peripheral circuit structure, a second contact pad in the cell array structure and connected to the first contact pad, a first chip through via penetrating at least a portion of the semiconductor substrate and the peripheral circuit structure and connected to the first contact pad, and a second chip through via penetrating at least a portion of the cell array structure and connected to the second contact pad, and the first chip through via of a first semiconductor chip is connected to the second chip through via of a second semiconductor chip.

### CROSS-REFERENCE TO RELATED APPLICATION

This application claims priority to and the benefit of Korean Patent Application No. 10-2024-0017688 filed in the Korean Intellectual Property Office on Feb. 5, 2024, the entire contents of which are incorporated herein by reference.

### BACKGROUND OF THE DISCLOSURE

### 1. Field

The present disclosure relates to a semiconductor device.

### 2. Description of the Related Art

Recently, the demand for portable devices has been rapidly increasing in the electronic product market, and as a result, there is a continuous demand for down-sizing and weight reduction of electronic components, such as semiconductor chips, mounted on these products. To realize the down-sizing and weight reduction of these electronic components, not only technology to reduce the individual sizes of the mounted components, but also a semiconductor device that integrates the semiconductor chips that make up the component are desirable. For example, to realize high performance and large capacity along with down-sizing and making more lightweight, the semiconductor device may have a cell over peri (COP) structure and may have a stacked structure of the semiconductor chips including a through silicon via (TSV).

### SUMMARY

The present disclosure provides a semiconductor device for increasing reliability and productivity.

According to an embodiment of the present disclosure, a semiconductor device includes: a package substrate; and semiconductor chips stacked on the package substrate, wherein each of the semiconductor chips respectively includes: a semiconductor substrate, a peripheral circuit structure and a cell array structure disposed to overlap each other in a vertical direction on the semiconductor substrate, a first contact pad in the peripheral circuit structure, a second contact pad in the cell array structure, the second contact pad being connected to the first contact pad, a first chip through via penetrating at least a portion of the semiconductor substrate and the peripheral circuit structure, the first chip through via being connected to the first contact pad, and a second chip through via penetrating at least a portion of the cell array structure, the second chip through via being connected to the second contact pad, and the first chip through via of a first semiconductor chip of the semiconductor chips is connected to the second chip through via of a second semiconductor chip of the semiconductor chips.

According to another embodiment of the present disclosure, a semiconductor device includes: a package substrate; and a first set of semiconductor chips stacked on the package substrate, wherein each semiconductor chip of the first set of semiconductor chips respectively includes: a first semiconductor substrate, a first peripheral circuit structure on the first semiconductor substrate, a first cell array structure on the first peripheral circuit structure, a first contact pad in the first peripheral circuit structure, a second contact pad in the first cell array structure, the second contact pad contacting the first contact pad, a contact insulating layer on a boundary between the first peripheral circuit structure and the first cell array structure, the contact insulating layer surrounding the first contact pad and the second contact pad, a first chip through via penetrating the first semiconductor substrate and first the peripheral circuit structure, the first chip through via being connected to the first contact pad, and a second chip through via penetrating the first cell array structure, the second chip through via being connected to the second contact pad, and wherein the first chip through via of a first semiconductor chip of the first set of semiconductor chips is connected to the second chip through via of a second semiconductor chip of the first set of semiconductor chips.

According to another embodiment of the present disclosure, a semiconductor device includes: a package substrate including a first surface and a second surface opposite to each other; a first substrate pad and a second substrate pad respectively disposed on the first surface and the second surface of the package substrate; an external connecting terminal on the first substrate pad; semiconductor chips respectively including a first surface and a second surface opposite to each other, the semiconductor chips being stacked on the second surface of the package substrate; a first chip pad and a second chip pad respectively disposed on the first surface and the second surface of each of the semiconductor chips; a first chip connecting terminal between the first chip pad of a first semiconductor chip and the second chip pad of a second semiconductor chip; a second chip connecting terminal between the first chip pad of a third semiconductor chip and the second substrate pad; an underfill member between adjacent semiconductor chips and between the package substrate and the lowermost semiconductor chip from among the semiconductor chips; and a molding member covering the package substrate and the semiconductor chips, wherein the semiconductor chips respectively include: a semiconductor substrate, a peripheral circuit structure on the semiconductor substrate, a cell array structure on the peripheral circuit structure, a first contact pad and a second contact pad contacting each other on a boundary between the peripheral circuit structure and the cell array structure, a contact insulating layer surrounding the first contact pad and the second contact pad, a first chip through via penetrating the semiconductor substrate and the peripheral circuit structure, the first chip through via being connected to the first contact pad and the first chip pad, and a second chip through via penetrating the cell array structure, the second chip through via being connected to the second contact pad and the second chip pad, and wherein the first chip through via of a semiconductor chip of the semiconductor chips is connected to the second chip through via of another semiconductor chip of the semiconductor chips.

According to the embodiments, the peripheral circuit structure and the cell array structure are vertically stacked, and the semiconductor chips including the through via are stacked, thereby improving characteristics and area efficiency of the semiconductor device.

### BRIEF DESCRIPTION OF THE DRAWINGS

FIG. 1 shows a cross-sectional view of a semiconductor device according to an embodiment.

FIG. 2 shows a partially enlarged view of a region R1 of FIG. 1.

FIG. 3 shows a cross-sectional view of a semiconductor chip included in a semiconductor device according to an embodiment.

FIG. 4 and FIG. 5 show partially enlarged views of a cross-section of a semiconductor device according to several embodiments.

FIG. 6 shows a cross-sectional view of a semiconductor device according to several embodiments.

FIG. 7 shows a cross-sectional view of a semiconductor chip included in a semiconductor device according to several embodiments.

FIG. 8 and FIG. 9 show cross-sections of a semiconductor device according to several embodiments.

FIG. 10 shows a partially enlarged view of a region R4 of FIG. 9.

FIG. 11 to FIG. 15 show cross-sections of a semiconductor device according to several embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Parts that are irrelevant to the description will be omitted to clearly describe the present disclosure, and the same elements will be designated by the same reference numerals throughout the specification.

The size and thickness of each configuration shown in the drawings are arbitrarily shown for better understanding and ease of description, but the present invention is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to another element, it can be directly connected or coupled to the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

The phrase “in a plan view” means viewing an object portion from the top, and the phrase “in a cross-sectional view” means viewing a cross-section of which the object portion is vertically cut from the side.

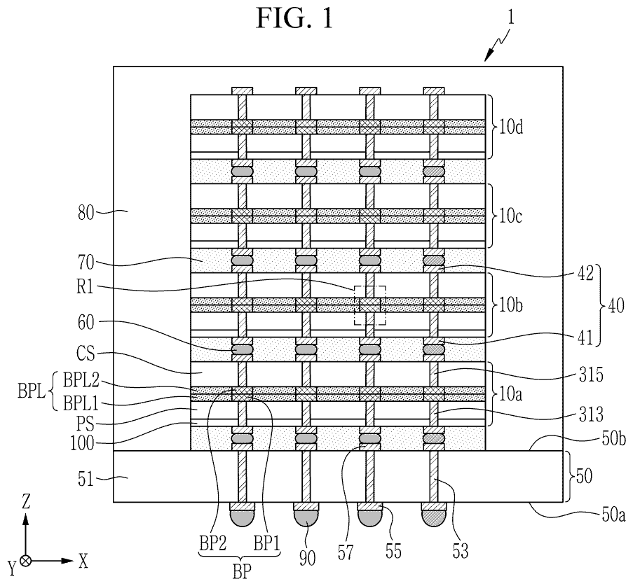

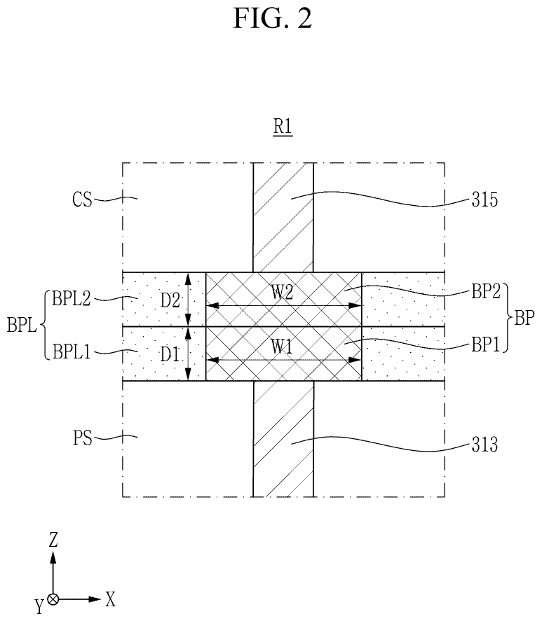

A semiconductor device according to an embodiment will now be described with reference to FIG. 1 and FIG. 2.

FIG. 1 shows a cross-sectional view of a semiconductor device according to an embodiment. FIG. 2 shows a partially enlarged view of a region R1 of FIG. 1.

Referring to FIG. 1 and FIG. 2, the semiconductor device 1 may include a package substrate 50, semiconductor chips 10a, 10b, 10c, and 10d, chip pads 40, a chip connecting terminal 60, an underfill member 70, and a molding member 80.

The package substrate 50 may include a first surface 50a and a second surface 50b facing each other. A direction that is parallel to a first surface 50a of the package substrate 50 may be defined to be a first direction (X), a direction that is parallel to the first surface 50a of the package substrate 50 and is perpendicular to the first direction (X) may be defined to be a second direction (Y), and a direction that is vertical to the first surface 50a of the package substrate 50 may be defined to be a third direction (Z).

The package substrate 50 may be one of a printed circuit board (PCB), a ceramic substrate, and an interposer.

In an embodiment, when the package substrate 50 is the interposer, the package substrate 50 may include a body 51, a substrate through via 53 for penetrating at least a portion of the body 51, and a first substrate pad 55 and a second substrate pad 57 respectively disposed on the first surface 50a and the second surface 50b of the package substrate 50.

The body 51 of the package substrate 50 may include, for example, silicon (Si). However, a material included in the body 51 is not limited thereto and may be changed in many ways. For example, the body 51 may include a semiconductor element such as germanium (Ge) and a compound semiconductor such as silicon carbide (SiC), gallium arsenide (GaAs), indium arsenide (InAs), or indium phosphide (InP).

The substrate through via 53 may penetrate the body 51 in the third direction (Z), and may electrically connect the first substrate pad 55 to the second substrate pad 57.

Although not shown in FIG. 1, the package substrate 50 may further include internal wires disposed in the body 51.

In several embodiments, the package substrate 50 may be a semiconductor chip including an integrated circuit therein. That is, the package substrate 50 may be a semiconductor chip including an electronic component such as transistors. For example, the package substrate 50 may be a die on a wafer level made of a semiconductor such as silicon (Si). However, the type of the package substrate 50 is not limited thereto and may be changed in many ways.

An external connecting terminal 90 may be disposed on the first surface 50a of the package substrate 50. The external connecting terminal 90 may be disposed on the first substrate pad 55. That is, the first substrate pad 55 may be disposed between the body 51 of the package substrate 50 and the external connecting terminal 90. The external connecting terminal 90 may electrically connect the semiconductor device 1 to an external device, or may be mounted on an external substrate.

The external connecting terminal 90 may be, for example, at least one of a solder ball, a pillar, and a conductive bump. However, the type of the external connecting terminal 90 is not limited thereto and may be changed in many ways.

The external connecting terminal 90 may include a conductive material. For example, the external connecting terminal 90 may include one of tin (Sn), silver (Ag), zinc (Zn), lead (Pb), or a combination thereof. However, the conductive material included by the external connecting terminal 90 is not limited thereto and may be changed in many ways.

The semiconductor chips 10a, 10b, 10c, and 10d may be stacked in the third direction (Z) that is the vertical direction on the second surface 50b of the package substrate 50. That is, the first semiconductor chip 10a, the second semiconductor chip 10b, the third semiconductor chip 10c, and the fourth semiconductor chip 10d may be sequentially stacked in the third direction (Z) on the second surface 50b of the package substrate 50. In other words, among the semiconductor chips 10a, 10b, 10c, and 10d, the first semiconductor chip 10a may be disposed on a lowermost end of the stack, and the fourth semiconductor chip 10d may be disposed on an uppermost end of the stack.

Planar areas of the first to fourth semiconductor chips 10a, 10b, 10c, and 10d may be less than a planar area of the package substrate 50. The respective planar areas of the first to fourth semiconductor chips 10a, 10b, 10c, and 10d may be substantially the same. However, relationships between the planar areas of the first to fourth semiconductor chips 10a, 10b, 10c, and 10d and the planar area of the package substrate 50 are not limited thereto and may be changed in many ways. The planar area of at least one of the first to fourth semiconductor chips 10a, 10b, 10c, and 10d may be different from the planar area of at least one other of the first to fourth semiconductor chips 10a, 10b, 10c, and 10d.

The respective first to fourth semiconductor chips 10a, 10b, 10c, and 10d may include a first surface and a second surface opposite to each other. Here, the first surfaces may represent bottom surfaces of the semiconductor chips 10a, 10b, 10c, and 10d, and the second surfaces may represent upper surfaces of the semiconductor chips 10a, 10b, 10c, and 10d. That is, the first surfaces may face the package substrate 50, and the second surfaces may face away from the package substrate 50.

The first surface of one of the first to fourth semiconductor chips 10a, 10b, 10c, and 10d may be stacked in the third direction (Z) to face the second surface of another thereof. For example, the first surface of the second semiconductor chip 10b may face the second surface of the first semiconductor chip 10a, and the second surface of the second semiconductor chip 10b may face the first surface of the third semiconductor chip 10c.

The first to fourth semiconductor chips 10a, 10b, 10c, and 10d may be logic chips or memory chips. For example, the semiconductor chips 10a, 10b, 10c, and 10d may be the memory chip of the same kind, some of the first to fourth semiconductor chips 10a, 10b, 10c, and 10d may be memory chips, and others may be logic chips.

FIG. 1 shows that the semiconductor device 1 includes four semiconductor chips, but the number of the semiconductor chips included by the semiconductor device 1 is not limited thereto and may be changed in many ways. For example, the semiconductor device 1 may include two, three, or equal to or more than five semiconductor chips. For another example, the semiconductor device 1 may include a number of the semiconductor chips equal to a multiple of four.

The memory chip may be, for example, a volatile memory chip such as a dynamic random access memory (DRAM) or a static RAM (SRAM) or a non-volatile memory chip such as a phase-change RAM (PRAM), a magnetoresistive RAM (MRAM), a ferroelectric RAM (FRAM), or a resistive RAM (RRAM).

In several embodiments, the first to fourth semiconductor chips 10a, 10b, 10c, and 10d may be high bandwidth memory (HBM) DRAMs. The logic chip may, for example, be a microprocessor, an analog component, or a digital signal processor.

Hereinafter, the first to fourth semiconductor chips 10a, 10b, 10c, and 10d will be assumed to be DRAMs.

Each of the semiconductor chips 10a, 10b, 10c, and 10d may respectively include a semiconductor substrate 100, a peripheral circuit structure PS, a cell array structure CS, a contact pad BP, a contact insulating layer BPL, chip through vias 313 and 315, and a chip pad 40.

In detail, regarding the respective semiconductor chips 10a, 10b, 10c, and 10d, the peripheral circuit structure PS and the cell array structure CS may be sequentially stacked on the semiconductor substrate 100. That is, the peripheral circuit structure PS may be disposed between the semiconductor substrate 100 and the cell array structure CS. However, a disposition relationship between the peripheral circuit structure PS and the cell array structure CS is not limited thereto and may be changed in many ways. For example, in several embodiments, the cell array structure CS and the peripheral circuit structure PS may be stacked on the semiconductor substrate 100. For example, the cell array structure CS may be disposed between the semiconductor substrate 100 and the cell array structure CS.

Hereinafter, a structure in which the cell array structure CS is disposed on the peripheral circuit structure PS will be assumed.

The semiconductor substrate 100 may be a silicon substrate, or may include other materials, for example, silicon germanium, an indium antimonide, a lead telluride compound, an indium arsenic, an indium phosphide, a gallium arsenic, and a gallium antimonide, and without being limited thereto, the materials included in the semiconductor substrate 100 may be changed in various ways.

In an embodiment, each of the semiconductor chips 10a, 10b, 10c, and 10d may be a bonded semiconductor chip in a chip-to-chip-structure in which the peripheral circuit structure PS is bonded to the cell array structure CS by a wafer bonding method.

The peripheral circuit structure PS may include a first surface and a second surface. The first surface of the peripheral circuit structure PS may face away from the cell array structure CS, and the second surface may face the cell array structure CS.

Here, the first surface of the peripheral circuit structure PS may represent a back side of the peripheral circuit structure PS, and the second surface of the peripheral circuit structure PS may represent a front side of the peripheral circuit structure PS.

The cell array structure CS may include a first surface and a second surface opposite to each other. The first surface of the cell array structure CS may face the peripheral circuit structure PS, and the second surface of the cell array structure CS may face away from the peripheral circuit structure PS.

In an embodiment, the second surface of the peripheral circuit structure PS and the first surface of the cell array structure CS may be a bonded surface of the peripheral circuit structure PS and the cell array structure CS. That is, the second surface of the peripheral circuit structure PS and the first surface of the cell array structure CS may be bonded and combined to each other to configure a bonding surface.

The contact pad BP and the contact insulating layer BPL may be disposed between the peripheral circuit structure PS and the cell array structure CS. That is, the contact pad BP may be disposed on a boundary between the peripheral circuit structure PS and the cell array structure CS.

The contact pad BP may include a first contact pad BP1 disposed in the peripheral circuit structure PS and a second contact pad BP2 disposed in the cell array structure CS.

The contact insulating layer BPL may include a first contact insulating layer BPL1 disposed in the peripheral circuit structure PS and a second contact insulating layer BPL2 disposed in the cell array structure CS.

In detail, the first contact pad BP1 and the first contact insulating layer BPL1 may be disposed in the second surface of the peripheral circuit structure PS. The upper surface of the first contact pad BP1 and the upper surface of the first contact insulating layer BPL1 may be coplanar, and may configure the second surface of the peripheral circuit structure PS. That is, the upper surface of the first contact pad BP1 and the upper surface of the first contact insulating layer BPL1 may be disposed on substantially the same level.

The first contact insulating layer BPL1 may surround the first contact pad BP1. For example, the first contact insulating layer BPL1 may surround a lateral surface of the first contact pad BP1. However, the disposition relationship of the first contact insulating layer BPL1 and the first contact pad BP1 is not limited thereto and may be changed in many ways. For example, the first contact insulating layer BPL1 may surround lateral surfaces and a bottom surface of the first contact pad BP1, and the bottom surface of the first contact insulating layer BPL1 may be disposed on a lower level than the bottom surface of the first contact pad BP1.

The second contact pad BP2 and the second contact insulating layer BPL2 may be disposed in the first surface of the cell array structure CS. The bottom surface of the second contact pad BP2 and the bottom surface of the second contact insulating layer BPL2 may be coplanar, and may configure the first surface of the cell array structure CS. That is, the bottom surface of the second contact pad BP2 and the bottom surface of the second contact insulating layer BPL2 may be disposed on substantially the same level.

The second contact insulating layer BPL2 may surround the second contact pad BP2. For example, the second contact insulating layer BPL2 may surround a lateral surface of the second contact pad BP2. However, the disposition relationship of the second contact insulating layer BP2 and the second contact pad BP2 is not limited thereto and may be changed in many ways. For example, the second contact insulating layer BPL2 may surround lateral surfaces and an upper surface of the second contact pad BP2, and the upper surface of the second contact insulating layer BPL2 may be disposed on a higher level than the upper surface of the second contact pad BP2.

The respective first contact pad BP1 and the first contact insulating layer BPL1 may be directly bonded to the second contact pad BP2 and the second contact insulating layer BPL2 on the boundary where the second surface of the peripheral circuit structure PS contacts the first surface of the cell array structure CS. For example, the respective first contact pad BP1 and the first contact insulating layer BPL1 may be bonded and combined to the second contact pad BP2 and the second contact insulating layer BPL2 by a hybrid bonding or a direct bonding. However, the method for the first contact pad BP1 and the first contact insulating layer BPL1 to be respectively bonded to the second contact pad BP2 and the second contact insulating layer BPL2 is not limited thereto and may be changed in many ways.

The boundary between the first contact pad BP1 and the second contact pad BP2 and the boundary between the first contact insulating layer BPL1 and the second contact insulating layer BPL2 may configure a bonding surface between the peripheral circuit structure PS and the cell array structure CS.

As shown in FIG. 2, the first contact pad BP1 and the second contact pad BP2 may respectively have a first width W1 and a second width W2 in the first direction (X) that is the horizontal direction, and may have a first thickness D1 and a second thickness D2 in the third direction (Z) that is the vertical direction.

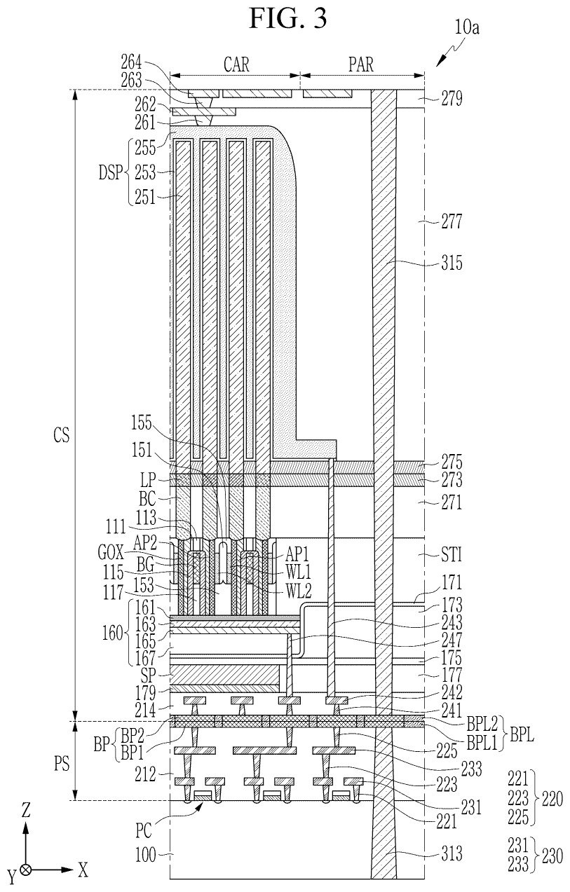

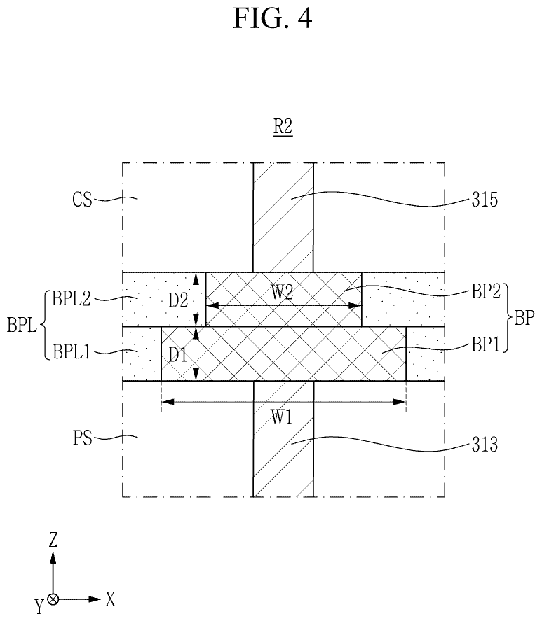

In an embodiment, the first width W1 and the second width W2 may be substantially the same, and the first thickness D1 and the second thickness D2 may be substantially the same. However, the relationship between the first width W1 and the second width W2 and the relationship between the first thickness D1 and the second thickness D2 are not limited thereto and may be changed in many ways. The detailed description thereof will be provided later with reference to FIG. 3 and FIG. 4.

In an embodiment, the first contact pad BP1 and the second contact pad BP2 may include the same material, and the first contact insulating layer BPL1 and the second contact insulating layer BPL2 may include the same material.

In detail, the first contact pad BP1 and the second contact pad BP2 may respectively include conductive materials such as copper (Cu), tungsten (W) nickel (Ni), gold (Au), and silver (Ag). For example, the first contact pad BP1 and the second contact pad BP2 may respectively include copper (Cu). However, the material included in the first contact pad BP1 and the second contact pad BP2 is not limited thereto and may be changed in many ways.

The first contact insulating layer BPL1 and the second contact insulating layer BPL2 may respectively include an insulating material such as a silicon oxide (SiO) and a silicon carbonitride (SiCN). For example, the first contact insulating layer BPL1 and the second contact insulating layer BPL2 may respectively include a silicon carbonitride (SiCN). However, the material included in the first contact insulating layer BPL1 and the second contact insulating layer BPL2 is not limited thereto and may be changed in many ways.

As described above, as the first contact pad BP1 and the second contact pad BP2 contact each other on the boundary between the peripheral circuit structure PS and the cell array structure CS, an electrical connection path between the peripheral circuit structure PS and the cell array structure CS may be provided.

The respective first to fourth semiconductor chips 10a, 10b, 10c, and 10d may include a first chip through via 313 disposed in the peripheral circuit structure PS and a second chip through via 315 disposed in the cell array structure CS.

In detail, the first chip through via 313 may penetrate at least a portion of the semiconductor substrate 100 and the peripheral circuit structure PS and may extend in the third direction (Z). The first chip through via 313 may be connected to the first contact pad BP1.

The second chip through via 315 may penetrate at least a portion of the cell array structure CS and may extend in the third direction (Z). The second chip through via 315 may be connected to the second contact pad BP2.

The chip pad 40 may be respectively disposed on the first surfaces and the second surfaces of each of the first to fourth semiconductor chips 10a, 10b, 10c, and 10d. The chip pad 40 may include a first chip pad 41 disposed on the first surfaces of each of the first to fourth semiconductor chips 10a, 10b, 10c, and 10d and a second chip pad 42 disposed on the second surfaces of each of the first to fourth semiconductor chips 10a, 10b, 10c, and 10d.

The first chip pad 41 disposed on the first surface of one of the first to fourth semiconductor chips 10a, 10b, 10c, and 10d (e.g., the first chip pad 41 of the second semiconductor chip 10b) may face the second chip pad 42 disposed on the second surface of another thereof (e.g., the second chip pad 42 of the first semiconductor chip 10a). That is, the first chip pad 41 and the second chip pad 42 may face each other among the first to fourth semiconductor chips 10a, 10b, 10c, and 10d that are adjacent to each other.

For example, the first chip pad 41 disposed on the first surface of the second semiconductor chip 10b may face the second chip pad 42 disposed on the second surface of the first semiconductor chip 10a. The second chip pad 42 disposed on the second surface of the second semiconductor chip 10b may face the first chip pad 41 disposed on the first surface of the third semiconductor chip 10c.

The first chip pad 41 of the first semiconductor chip 10a disposed on a lowermost end from among the first to fourth semiconductor chips 10a, 10b, 10c, and 10d that are adjacent to each other may face the second substrate pad 57 disposed on the second surface 50b of the package substrate 50.

The first chip pad 41 and the second chip pad 42 may include the same conductive material. For example, the first chip pad 41 and the second chip pad 42 may include at least one of copper (Cu), aluminum (Al), nickel (Ni), tungsten (W), platinum (Pt), and gold (Au). However, the material included by the first chip pad 41 and the second chip pad 42 is not limited thereto and may be changed in many ways.

The chip connecting terminal 60 may be respectively disposed between adjacent semiconductor chips from among the first to fourth semiconductor chips 10a, 10b, 10c, and 10d. The chip connecting terminal 60 may be disposed between the first semiconductor chip 10a and the package substrate 50. The chip connecting terminal 60 may electrically connect the first to fourth semiconductor chips 10a, 10b, 10c, and 10d to each other and to the package substrate 50.

In detail, the chip connecting terminal 60 may be disposed between the first chip pad 41 and the second chip pad 42. That is, the chip connecting terminal 60 may be disposed between the first chip pad 41 of one of the first to fourth semiconductor chips 10a, 10b, 10c, and 10d and the second chip pad 42 of another thereof.

Hence, the first chip through via 313 of one of the first to fourth semiconductor chips 10a, 10b, 10c, and 10d and the second chip through via 315 of another thereof may be electrically connected to each other by the chip connecting terminal 60.

Hence, the first chip through via 313 and the second chip through via 315 connected to the first chip pad 41 of one of the first to fourth semiconductor chips 10a, 10b, 10c, and 10d and the second chip pad 42 of another thereof, respectively, may be connected to each other by the chip connecting terminal 60.

For example, the first chip through via 313 connected to the first chip pad 41 of the second semiconductor chip 10b and the second chip through via 315 connected to the second chip pad 42 of the first semiconductor chip 10a may be electrically connected to each other by the chip connecting terminal 60 disposed between the first chip pad 41 and the second chip pad 42.

The chip connecting terminal 60 may be disposed between the first semiconductor chip 10a disposed on the lowermost end from among the first to fourth semiconductor chips 10a, 10b, 10c, and 10d and the second surface 50b of the package substrate 50. That is, the chip connecting terminal 60 may be disposed between the first chip pad 41 of the first semiconductor chip 10a and the second substrate pad 57 of the package substrate 50 and may electrically connect the first semiconductor chip 10a to the package substrate 50.

The chip connecting terminal 60 may be, for example, at least one of a solder ball, a pillar, and a conductive bump. However, types of the chip connecting terminal 60 are not limited thereto and may be changed in many ways.

The chip connecting terminal 60 may include a conductive material. For example, the chip connecting terminal 60 may include one of tin (Sn), silver (Ag), zinc (Zn), lead (Pb), or combinations thereof. However, the conductive material included by the chip connecting terminal 60 is not limited thereto and may be changed in many ways.

The underfill member 70 may be respectively disposed between the package substrate 50 and the first semiconductor chip 10a and between adjacent semiconductor chips from among the first to fourth semiconductor chips 10a, 10b, 10c, and 10d.

The underfill member 70 may fill a gap region that remains after the second substrate pad 57, the first chip pad 41, and the chip connecting terminal 60 are formed between the package substrate 50 and the first semiconductor chip 10a.

The underfill member 70 may fill a gap region that remains after the chip pad 40 and the chip connecting terminal 60 are formed between adjacent semiconductor chips from among the first to fourth semiconductor chips 10a, 10b, 10c, and 10d.

The underfill member 70 may include an insulating material. For example, the underfill member 70 may include an epoxy-based polymer. However, the material included by the underfill member 70 is not limited thereto and may be changed in many ways.

FIG. 1 shows that respective sides of the underfill member 70 and respective sides of the first to fourth semiconductor chips 10a, 10b, 10c, and 10d are arranged on substantially the same boundary, but the inventive concept is not limited thereto. For example, ends of respective sides of the underfill member 70 may protrude from the respective sides of the first to fourth semiconductor chips 10a, 10b, 10c, and 10d, and may have a curved shape that is convex toward a first side and a second side of the first direction (X).

As described, when the underfill member 70 protrudes from the respective sides of the first to fourth semiconductor chips 10a, 10b, 10c, and 10d in the first direction (X), the underfill member 70 may cover at least a portion of the respective sides of the first to fourth semiconductor chips 10a, 10b, 10c, and 10d.

The molding member 80 may be disposed on the package substrate 50. The molding member 80 may cover a portion of the second surface 50b of the package substrate 50, lateral surfaces of the first to third semiconductor chips 10a, 10b, and 10c, a lateral surface and an upper surface of the fourth semiconductor chip 10d, and a lateral surface of the underfill member 70.

The molding member 80 may cover the second chip pad 42 disposed on the second surface of the fourth semiconductor chip 10d.

The molding member 80 may include an insulating material. For example, the molding member 80 may include a polymer such as an epoxy molding compound (EMC). For another example, the molding member 80 may include an epoxy-based material, a thermosetting material, a thermoplastic material, and a UV processed material. However, the material included by the molding member 80 is not limited thereto and may be changed in many ways.

FIG. 3 shows a cross-sectional view of a semiconductor chip included in a semiconductor device according to an embodiment.

The first to fourth semiconductor chips 10a, 10b, 10c, and 10d included in the semiconductor device 1 will now be described in detail.

FIG. 3 shows a cross-section of the first semiconductor chip 10a from among the first to fourth semiconductor chips 10a, 10b, 10c, and 10d, and the second to fourth semiconductor chips 10b, 10c, and 10d may have substantially the same configuration and structure as the first semiconductor chip 10a. However, the embodiment is not limited thereto, and in several embodiments, at least one of the first to fourth semiconductor chips 10a, 10b, 10c, and 10d may have a different configuration and structure.

The first semiconductor chip 10a will be mainly described, and the description on the first semiconductor chip 10a may be applied to the second to fourth semiconductor chips 10b, 10c, and 10d in substantially the same way.

Referring to FIG. 3, the first semiconductor chip 10a included in the semiconductor device 1 may be a DRAM. For example, the first semiconductor chip 10a may include memory cells including a vertical channel transistor (VCT). However, this is an example, and configurations, structures, and types of the first semiconductor chip 10a are not limited thereto and may be changed in many ways.

The first semiconductor chip 10a may include a semiconductor substrate 100, a peripheral circuit structure PS disposed on the semiconductor substrate 100, and a cell array structure CS disposed in the peripheral circuit structure PS.

The semiconductor substrate 100 may include a cell array region CAR, and a peripheral circuit region PAR defined around the cell array region CAR. For example, the peripheral circuit region PAR may be disposed near the cell array region CAR. However, the disposition relationship between the cell array region CAR and the peripheral circuit region PAR is not limited thereto and may be changed in many ways.

The peripheral circuit structure PS may be disposed in the cell array region CAR and the peripheral circuit region PAR on the semiconductor substrate 100. That is, a portion of the peripheral circuit structure PS may be disposed in the cell array region CAR of the semiconductor substrate 100, and another portion thereof may be disposed in the peripheral circuit region PAR.

The peripheral circuit structure PS may include a peripheral circuit PC, a peripheral contact plug 220, a peripheral circuit wire 230, a peripheral circuit insulating layer 212, a first contact insulating layer BPL1, and a first contact pad BP1.

The peripheral circuit PC may, for example, be a sensing transistor, a transmitting transistor, and/or a driving transistor. However, the types of the transistors of the peripheral circuit PC may be changeable according to design and disposition of the semiconductor chips.

The peripheral circuit PC may be disposed on the semiconductor substrate 100. The peripheral circuit PC may include a peripheral circuit gate insulating layer and a peripheral circuit conductive pattern sequentially stacked on the semiconductor substrate 100.

The peripheral circuit gate insulating layer may include a silicon oxide, a silicon oxynitride, a high dielectric (high-k) material that has a higher dielectric constant than the silicon oxide, and combinations thereof. The high dielectric (high-k) material may, for example, include at least one of a metal oxide, a metal oxynitride, a metal silicon oxide, and a metal silicon oxynitride, but is not limited thereto.

The peripheral circuit conductive pattern may include a conductive material. For example, the peripheral circuit conductive pattern may include at least one of a doped semiconductor material, a conductive metal nitride, a conductive metal silicon nitride, a metal carbonitride, a conductive metal silicide, a conductive metal oxide, a 2-dimensional (2D) material, and a metal.

The peripheral circuit insulating layer 212 may cover the peripheral circuit PC. The peripheral circuit insulating layer 212 may include an insulating material. For example, the peripheral circuit insulating layer 212 may include a silicon oxide, a silicon nitride layer, a silicon oxynitride layer, and/or a low dielectric layer. However, it is not limited thereto.

The peripheral contact plug 220 and the peripheral circuit wire 230 may be disposed in the peripheral circuit insulating layer 212.

The peripheral contact plug 220 may include first peripheral contact plugs 221, second peripheral contact plugs 223, and third peripheral contact plugs 225.

The peripheral circuit wire 230 may include first peripheral circuit wires 231 and second peripheral circuit wires 233.

The first peripheral circuit wires 231 may be connected to the peripheral circuit PC through the first peripheral contact plugs 221. That is, the first peripheral circuit wires 231 may be connected to source/drain regions disposed on at least one side of the peripheral circuit PC through the first peripheral contact plugs 221. The first peripheral circuit wires 231 and the second peripheral circuit wires 233 may be connected by the second peripheral contact plug 223.

The first contact insulating layer BPL1 and the first contact pads BP1 may be disposed on the peripheral circuit insulating layer 212. The first contact pads BP1 may be connected to the second peripheral circuit wires 233 through the third peripheral contact plugs 225.

Hence, the first contact pads BP1 may be connected to the peripheral circuit PC through the second peripheral circuit wires 233, the second peripheral contact plugs 223, the first peripheral circuit wires 231, and the first peripheral contact plugs 221. However, a connection relationship among the peripheral circuit PC, the peripheral contact plug 220, the peripheral circuit wire 230, and the first contact pads BP1 included in the peripheral circuit structure PS is not limited thereto and may be changed in many ways.

The first chip through via 313 may be connected to the first contact pad BP1 through the semiconductor substrate 100 and the peripheral circuit structure PS. That is, the first chip through via 313 may be connected to one of the first contact pads BP1 through the semiconductor substrate 100 and the peripheral circuit insulating layer 212 of the peripheral circuit structure PS.

A first end of the first chip through via 313 may be connected to the first contact pad BP1, and a second end thereof may be connected to the first chip pad 41 of FIG. 1 of the first semiconductor chip 10a. For example, the first chip through via 313 may extend through the entire semiconductor substrate 100 and through the entire peripheral circuit structure PS in the vertical direction (Z). For example, a side wall of the first chip through via 313 may be a single, continuous, uninterrupted surface from the bottom of the semiconductor substrate 100 to the top of the peripheral circuit structure PS.

FIG. 3 shows that the first chip through via 313 is directly connected to the first contact pad BP1, but the connection relationship between the first chip through via 313 and the first contact pad BP1 is not limited thereto and may be changed in many ways. For example, the first chip through via 313 may be connected to the first contact pad BP1 through the peripheral contact plug 220 and the peripheral circuit wire 230.

In several embodiments, the first chip through via 313 may be simultaneously electrically connected to the first contact pad BP1 and the peripheral circuit PC through the peripheral contact plug 220 and the peripheral circuit wire 230.

A width of the first chip through via 313 in the first direction (X) may be reduced in accordance with a distance to the first contact pad BP1 according to an aspect ratio on the cross-section. For example, the width of the first chip through via 313 may narrow as it approaches the first contact pad BP1. However, the cross-sectional shape of the first chip through via 313 is not limited thereto and may be changed in many ways. For example, the width of the first chip through via 313 in the first direction (X) may be increased in accordance with a distance to the first contact pad BP1 according to the aspect ratio on the cross-section.

The first chip through via 313 may include a conductive material. For example, the conductive material may include at least one of metals such as aluminum (Al), tungsten (W), titanium (Ti), tantalum (Ta), or copper (Cu) or combinations thereof. However, the conductive material is not limited thereto and may be changed in many ways.

The cell array structure CS may be disposed in the peripheral circuit structure PS. That is, the cell array structure CS may overlap the peripheral circuit structure PS in the third direction (Z) that is the vertical direction.

The cell array structure CS disposed in the cell array region CAR may include a second contact insulating layer BPL2, second contact pads BP, bit lines BL, a shield pattern SP, active patterns AP1 and AP2, word lines WL1 and WL2, back gate electrodes BG, buried contacts BC, landing pads LP, and a capacitor DSP, and the cell array structure CS disposed in the peripheral circuit region PAR may include a second chip through via 315.

As described above, the cell array structure CS and the peripheral circuit structure PS may be combined and connected to each other by the contact pad BP and the contact insulating layer BPL. That is, the first contact pads BP1 and the first contact insulating layer BPL1 disposed in the peripheral circuit structure PS may be bonded and connected to the respective second contact pads BP2 and the second contact insulating layer BPL2 disposed in the cell array structure CS. The detailed description thereof is substantially the same as the above-described content so it will be omitted.

The semiconductor chip 10a may further include a cell array insulating layer 214 disposed on the second contact pads BP2 and the second contact insulating layer BPL2, lower contact plugs 241 disposed in the cell array insulating layer 214, and lower wires 242. The cell array insulating layer 214 may include an insulating material. For example, the cell array insulating layer 214 may include one of a silicon oxide, a silicon nitride, a silicon oxynitride, and combinations thereof.

The lower wires 242 may be connected to components disposed in the cell array structure CS, and the lower contact plugs 241 may connect the second contact pads BP2 to the lower wires 242.

Accordingly, the first contact pads BP1 disposed in the peripheral circuit structure PS and the second contact pads BP2 disposed in the cell array structure CS are bonded to each other to provide an electrical connection path between the peripheral circuit structure PS and the cell array structure CS. For example, the lower wires 242 connected to the components included in the cell array structure CS may be electrically connected to at least one of the peripheral circuit PC, the peripheral contact plug 220, and the peripheral circuit wire 230 included in the peripheral circuit structure PS by the contact pads BP.

The peripheral contact plug 220 and the peripheral circuit wire 230 disposed in the peripheral circuit structure PS and the lower contact plugs 241 and the lower wires 242 disposed in the cell array structure CS may respectively include a conductive material. For example, the conductive material may include aluminum (Al), tungsten (W), titanium (Ti), copper (Cu), and tantalum (Ta). However, the conductive material is not limited thereto and may be changed in many ways.

The bit lines BL may extend in parallel to each other in the first direction (X) traversing the second direction (Y). The bit lines BL may be spaced from each other in the second direction (Y) on the semiconductor substrate 100.

The respective bit lines BL (160) may include a polysilicon layer 161, a first metal layer 163, a second metal layer 165, and a bit line hard mask layer 167 that are sequentially stacked.

The polysilicon layer 161 may include impurity-doped polysilicon, and the first metal layer 163 and the second metal layer 165 may include a conductive material. For example, the first metal layer 163 may include a conductive metal nitride (e.g., titanium nitride, nitride tantalum, etc.), and the second metal layer 165 may include a metal (e.g., tungsten, titanium, tantalum, etc.). At least one of the first metal layer 163 and the second metal layer 165 may include a metal silicide such as titanium silicide, cobalt silicide, or nickel silicide. However, the material included in the first metal layer 163 and the second metal layer 165 is not limited thereto and may be changed in many ways.

The bit line hard mask layer 167 may include an insulating material such as silicon nitride or silicon oxynitride.

The bit lines BL may be disposed near the peripheral circuit structure PS. Hence, the electrical connection path among the bit lines BL and the peripheral circuits PC may be reduced.

The shield pattern SP may be disposed between the peripheral circuit structure PS and the bit lines BL.

The shield pattern SP may be made of a conductive material, and the shield pattern SP may, for example, include metal materials such as tungsten (W), titanium (Ti), nickel (Ni), and cobalt (Co). For another example, the shield pattern SP may include a conductive 2D material such as graphene.

The first semiconductor chip 10a may further include a spacer insulating layer 175 disposed between the shield pattern SP and the bit line BL. The spacer insulating layer 175 may have a substantially uniform thickness and may be conformally disposed between the bit line BL and the shield pattern SP.

The spacer insulating layer 175 may, for example, include a silicon oxide, a silicon nitride layer, a silicon oxynitride layer, and/or a low dielectric layer.

The first semiconductor chip 10a may further include a shield capping pattern 179 disposed on the shield pattern SP, a first lower insulation layer 177 disposed between the spacer insulating layer 175 and the cell array insulating layer 214, a second lower insulation layer 173 disposed on the spacer insulating layer 175, a bit line etch stopper 171 disposed between the bit line BL and the spacer insulating layer 175, and a cell region shallow trench isolator STI disposed on the second lower insulation layer 173.

The shield capping pattern 179 may be disposed on the shield pattern SP, and the shield capping pattern 179 may contact the cell array insulating layer 214.

The first lower insulation layer 177 may be disposed on the cell array insulating layer 214. An upper surface of the first lower insulation layer 177 may contact the spacer insulating layer 175, and a lateral surface of the first lower insulation layer 177 may contact a terminal of the shield pattern SP and a terminal of the shield capping pattern 179.

The second lower insulation layer 173 may be disposed on the spacer insulating layer 175. A lateral surface of the second lower insulation layer 173 may face a terminal of the bit line BL.

The bit line etch stopper 171 may be disposed between the bit line BL and the spacer insulating layer 175. The bit line etch stopper 171 may extend along a lower surface and a lateral surface of the bit line BL. The bit line etch stopper 171 may be disposed on the second lower insulation layer 173, and may extend along an upper surface and a lateral surface of the second lower insulation layer 173.

The cell region shallow trench isolator STI may be disposed on the second lower insulation layer 173. A portion of the bit line etch stopper 171 may be disposed between the cell region shallow trench isolator STI and the second lower insulation layer 173.

The shield capping pattern 179, the first lower insulation layer 177, the second lower insulation layer 173, the bit line etch stopper 171, and the cell region shallow trench isolator STI may include a silicon oxide, a silicon nitride layer, a silicon oxynitride layer, and/or a low dielectric layer.

The first semiconductor chip 10a may further include a bit line contact plug 247.

The bit line contact plug 247 may be connected to a peripheral portion of the end of the bit line BL that does not overlap the shield pattern SP in the third direction (Z).

The bit line BL may be connected to the second contact pad BP2 through the bit line contact plug 247 penetrating the cell array insulating layer 214, the first lower insulation layer 177, the spacer insulating layer 175, the bit line etch stopper 171, and the bit line hard mask layer 167.

The bit line BL connected to the second contact pad BP2 may be connected to the peripheral circuit wires 230 and/or the peripheral circuit PC disposed in the peripheral circuit structure PS through the first contact pad BP1. However, the connection relationship between the bit line BL and the peripheral circuit structure PS is not limited thereto and may be changed in many ways.

Although not shown in FIG. 3, the first semiconductor chip 10a according to several embodiments may further include a shield contact plug for connecting the shield pattern SP and the peripheral circuit structure PS.

The first active patterns AP1 and the second active patterns AP2 may be disposed on the bit line BL. The first active patterns AP1 and the second active patterns AP2 may be alternately disposed and may extend in the second direction (Y).

The first active patterns AP1 and the second active patterns AP2 may be made of a monocrystalline semiconductor material. For example, the first active patterns AP1 and the second active patterns AP2 may be made of a monocrystalline silicon.

The first and second active patterns AP1 and AP2 may be controlled by the first and second word lines WL1 and WL2 and the back gate electrodes BG when the semiconductor chip is operated. The first and second active patterns AP1 and AP2 are made of a monocrystalline semiconductor material, thereby improving a leakage current characteristic of the semiconductor memory device.

The back gate electrodes BG may be disposed on the bit line BL and shield pattern SP. The first active pattern AP1 may be disposed on the first side of the back gate electrode BG, and the second active pattern AP2 may be disposed on the second side of the back gate electrode BG. A height of the back gate electrode BG in the third direction (Z) may be less than heights of the first and second active patterns AP1 and AP2 in the third direction (Z).

The first active pattern AP1 may be disposed between the first word line WL1 and the back gate electrode BG. The second active pattern AP2 may be disposed between the second word line WL2 and the back gate electrode BG.

The back gate electrode BG may include a conductive material. For example, the back gate electrode BG may include at least one of doped polysilicon, conductive metal nitride, conductive metal silicon nitride, metal carbonitride, conductive metal silicide, conductive metal oxide, 2D material, and metal.

The back gate electrodes BG may receive a negative voltage when operating the semiconductor chip, and may increase a threshold voltage of the vertical channel transistor. That is, as the vertical channel transistor becomes smaller, the threshold voltage may be reduced. The negative voltage is applied to the back gate electrodes BG to prevent the reduction of the threshold voltage and thereby to prevent the leakage current characteristic from being deteriorated.

The first semiconductor chip 10a may further include a first back gate separating pattern 111, a second back gate separating pattern 113, a back gate insulating pattern 115, and a back gate capping pattern 117.

The first back gate separating pattern 111 and the second back gate separating pattern 113 may be disposed between the first and second active patterns AP1 and AP2 that are disposed adjacent to each other.

The first back gate separating pattern 111 may contact the first and second active patterns AP1 and AP2. The second back gate separating pattern 113 may be spaced from the first and second active patterns AP1 and AP2 with the first back gate separating pattern 111 therebetween.

The back gate electrode BG may include a first surface and a second surface opposite to each other in the third direction (Z) that is the vertical direction. The first surface of the back gate electrode BG may face the bit line BL and the shield pattern SP, and the second surface of the back gate electrode BG may face the first back gate separating pattern 111 and the second back gate separating pattern 113. That is, the first back gate separating pattern 111 and the second back gate separating pattern 113 may be disposed on the second surface of the back gate electrode BG.

The first back gate separating pattern 111 and the second back gate separating pattern 113 may include an insulating material. The first back gate separating pattern 111 and the second back gate separating pattern 113 may respectively include at least one of a silicon oxide, a silicon oxynitride layer, and a silicon nitride layer. For example, the first back gate separating pattern 111 may include a silicon oxide, and the second back gate separating pattern 113 may include at least one of a silicon oxynitride layer and a silicon nitride layer. However, the material included in the first back gate separating pattern 111 and the second back gate separating pattern 113 is not limited thereto and may be changed in many ways.

The back gate insulating pattern 115 may be disposed between the back gate electrode BG and the first active pattern AP1 and between the back gate electrode BG and the second active pattern AP2. The back gate insulating pattern 115 may also be disposed between the back gate electrode BG and a gate insulating pattern GOX to be described.

The back gate insulating pattern 115 may, for example, include a silicon oxide, a silicon oxynitride layer, a high dielectric insulating layer that has a higher dielectric constant than the silicon oxide, and combinations thereof.

The back gate capping pattern 117 may cover the back gate electrode BG between the bit line BL and the back gate electrode BG. That is, the back gate capping pattern 117 may cover the first surface of the back gate electrode BG.

The back gate capping pattern 117 may include an insulating material. For example, the back gate capping pattern 117 may include one of a silicon oxide, a silicon nitride, a silicon oxynitride, and combinations thereof. However, the material included by the back gate capping pattern 117 is not limited thereto and may be changed in many ways.

The first word line WL1 and the second word line WL2 may be disposed on the bit line BL and the shield pattern SP.

The first and second word lines WL1 and WL2 may respectively include a first surface and a second surface opposite to each other in the third direction (Z). The first surfaces of the respective first and second word lines WL1 and WL2 may face the bit line BL and the shield pattern SP, and the second surfaces thereof may face a buried contact BC and a second gate capping pattern 155 to be described.

The first word line WL1 and the second word line WL2 may be disposed between the bit line BL and the buried contact BC and may extend in the third direction (Z).

The first and second word lines WL1 and WL2 may include a conductive material, for example, at least one of doped polysilicon, conductive metal nitride, conductive metal silicon nitride, metal carbonitride, conductive metal silicide, conductive metal oxide, 2D material, and metal.

Although not shown in FIG. 3, the first semiconductor chip 10a according to several embodiments may further include a word line contact plug for connecting the word lines WL1 and WL2 and the peripheral circuit structure PS to each other.

The first semiconductor chip 10a may further include a gate insulating pattern GOX disposed on lateral surfaces of the word lines WL1 and WL2, a gate separating pattern 151 disposed between the word lines WL1 and WL2, and a first gate capping pattern 153 and a second gate capping pattern 155 respectively disposed on the first surfaces and the second surfaces of the word lines WL1 and WL2.

The gate insulating pattern GOX may extend in the third direction (Z) between the active patterns AP1 and AP2 and the word lines WL1 and WL2, and may be disposed between the active patterns AP1 and AP2 and the first and second gate capping patterns 153 and 155.

A portion of the gate insulating pattern GOX may be disposed on a lateral surface of the cell region shallow trench isolator STI. That is, the portion of the gate insulating pattern GOX may be disposed between the cell region shallow trench isolator STI and the first gate capping pattern 153. The gate insulating pattern GOX disposed on the cell region shallow trench isolator STI may remain during a process for patterning the gate insulating pattern GOX.

The gate insulating pattern GOX may be made of a silicon oxide, a silicon oxynitride layer, a high dielectric layer that has a higher dielectric constant than the silicon oxide, or combinations thereof. The high dielectric layer may be made of a metal oxide or a metal oxidation nitride. For example, the high dielectric layer usable as the gate insulating pattern GOX may be made of HfO₂, HfSiO, HfSION, HfTaO, HfTiO, HfZrO, ZrO₂, Al₂O₃, or combinations thereof, but is not limited thereto.

The gate separating pattern 151 may be disposed between the first and second word lines WL1 and WL2. The gate separating pattern 151 may be disposed between the first and second gate capping patterns 153 and 155. The gate separating pattern 151 may contact the first and second word lines WL1 and WL2. The first and second word lines WL1 and WL2 may be separated by the gate separating pattern 151. The gate separating pattern 151 may extend in the third direction (Z) between the first and second word lines WL1 and WL2.

The first gate capping pattern 153 may be disposed between the spacer insulating layer 175 and the first and second word lines WL1 and WL2 and between the spacer insulating layer 175 and the gate separating pattern 151.

In detail, the first gate capping pattern 153 may be disposed on the first surfaces of the first and second word lines WL1 and WL2 and the first surface of the gate separating pattern 151. The first gate capping pattern 153 may surround the first surface of the gate separating pattern 151 and a portion of the respective sides of the gate separating pattern 151.

As shown in FIG. 3, the first gate capping pattern 153 may cover the first surface of the second word line WL2 and an end of the second word line WL2. The first gate capping pattern 153 covering the end of the second word line WL2 may oppose the cell region shallow trench isolator STI with the gate insulating pattern GOX therebetween. The disposition relationship between the second word line WL2 and the first gate capping pattern 153 may be substantially identically applied to the disposition relationship of the first word line WL1 and the first gate capping pattern 153.

The second gate capping pattern 155 may be disposed between the first and second word lines WL1 and WL2 and a contact interlayer insulating layer 271.

In detail, the second gate capping pattern 155 may be disposed on the second surfaces of the first and second word lines WL1 and WL2 and the second surface of the gate separating pattern 151.

The second gate capping pattern 155 may surround the second surface of the gate separating pattern 151 and a portion of the respective sides of the gate separating pattern 151. That is, the second gate capping pattern 155 may extend in the second direction (Y) that is the horizontal direction on the second surface of the gate separating pattern 151, and may extend in the third direction (Z) that is the vertical direction on the respective sides of the gate separating pattern 151.

The gate separating pattern 151, the first gate capping pattern 153, and the second gate capping pattern 155 may include a silicon oxide, a silicon nitride, and combinations thereof. They may include insulating materials. For example, the gate separating pattern 151 may include a silicon oxide, and the first and second gate capping patterns 153 and 155 may include a silicon nitride.

The first semiconductor chip 10a may further include a contact interlayer insulating layer 271, a pad separating insulating layer 273, and a contact etch stopper 275.

The contact interlayer insulating layer 271, the pad separating insulating layer 273, and the contact etch stopper 275 may include a silicon oxide, a silicon nitride, and combinations thereof. They may include insulating materials.

The contact interlayer insulating layer 271 may be disposed on the active patterns AP1 and AP2. The contact interlayer insulating layer 271 may cover the first and second back gate separating patterns 111 and 113, the second gate capping pattern 155, and the cell region shallow trench isolator STI.

In the cell array structure CS disposed in the cell array region CAR, the buried contact BC, the landing pad LP, and the capacitor DSP may be sequentially stacked.

The buried contacts BC may penetrate the contact interlayer insulating layer 271. The buried contacts BC may be respectively connected to the first and second active patterns AP1 and AP2. The buried contacts BC that are adjacent to each other may be separated from each other by the contact interlayer insulating layer 271.

The buried contacts BC may include a conductive material. For example, they may include at least one of doped polysilicon, conductive metal nitride, conductive metal silicon nitride, metal carbonitride, conductive metal silicide, conductive metal oxide, 2D material, and metal.

The landing pads LP may be disposed on the buried contact BC. The pad separating insulating layer 273 may be disposed on the contact interlayer insulating layer 271. The pad separating insulating layers 273 may be disposed between the landing pads LP. An upper surface of the landing pad LP may be substantially coplanar with the upper surface of the pad separating insulating layer 273.

The landing pad LP may include a conductive material. The conductive material may, for example, include at least one of doped polysilicon, conductive metal nitride, conductive metal silicon nitride, metal carbonitride, conductive metal silicide, conductive metal oxide, 2D material, and metal.

The capacitors DSP may be respectively disposed on the landing pads LP. The capacitors DSP may be respectively connected to the first and second active patterns AP1 and AP2. The capacitors DSP may completely or partly overlap the landing pads LP in the third direction (Z). The capacitors DSP may contact an entire or partial upper surface of the respective landing pads LP.

The respective capacitors DSP may include a cell lower electrode 251, a cell upper electrode 255, and a cell dielectric layer 253 disposed between the cell lower electrode 251 and the cell upper electrode 255. The cell lower electrode 251 may penetrate the contact etch stopper 275 to contact the landing pad LP. The cell lower electrode 251 may extend in the third direction (Z) that is the vertical direction on the landing pad LP.

The cell lower electrode 251 may include a metal, a conductive metal nitride, and combinations thereof. For example, the cell lower electrode 251 may be made of TIN, Ru, TaN, WN, Pt, Ir, or combinations thereof. However, the material included in the cell lower electrode 251 is not limited thereto and may be changed in many ways.

The cell dielectric layer 253 may be conformally disposed along a profile of the upper surface and the lateral surface of the cell lower electrode 251. That is, the cell dielectric layer 253 may cover the lateral surface and the upper surface of the cell lower electrode 251. A portion of the cell dielectric layer 253 may be disposed on the upper surface of the contact etch stopper 275. That is, the portion of the cell dielectric layer 253 may be disposed between the contact etch stopper 275 and the cell upper electrode 255.

The cell dielectric layer 253 may include a tantalum oxide (Ta₂O₅), an aluminum oxide (Al₂O₃), a titanium oxide (TiO₂), and combinations thereof. However, without being limited thereto, the material included by the cell dielectric layer 253 may be changed in many ways.

The cell upper electrode 255 may be disposed on the cell dielectric layer 253. The cell upper electrode 255 may cover the cell dielectric layer 253. That is, the cell upper electrode 255 may cover the upper surface and the lateral surface of the cell dielectric layer 255.

The cell upper electrode 255 may include a protrusion extending in the first direction (X) that is the horizontal direction from a portion extending along the lateral surface of the cell dielectric layer 253 and disposed on the contact etch stopper 275. That is, the protrusion of the cell upper electrode 255 may correspond to a terminal of the cell upper electrode 255, and the terminal of the cell upper electrode 255 may be disposed on the contact etch stopper 275.

The protrusion of the cell upper electrode 255 may extend in the horizontal direction from the cell upper electrode 255 contacting the portion of the cell dielectric layer 253 that contacts the contact etch stopper 275. The protrusion of the cell upper electrode 255 may be disposed in the cell array region CAR and the peripheral circuit region PAR.

The first semiconductor chip 10a may further include a capacitor contact plug 243 for connecting the cell upper electrode 255 to the second contact pad BP2.

The capacitor contact plug 243 may penetrate the cell dielectric layer 253, the contact etch stopper 275, and the insulating layers disposed between the second contact insulating layer BPL2 and the pad separating insulating layer 273 and may electrically connect the cell upper electrode 255 to the second contact pad BP2.

For example, the cell upper electrode 255 may be connected to the second contact pad BP2 through the lower wire 242 connected to the capacitor contact plug 243 and the lower contact plug 241.

As the first contact pad BP1 contacts the second contact pad BP2, the cell upper electrode 255 connected to the second contact pad BP2 may be connected to the peripheral circuit wires 230 disposed in the peripheral circuit structure PS and/or the peripheral circuit PC. However, the connection relationship between the cell upper electrode 255 and the peripheral circuit structure PS is not limited thereto and may be changed in many ways.

The cell upper electrode 255 may include a metal material such as W, Ti, Ru, or SiGe. For example, the cell upper electrode 255 may include tungsten (W). However, the material included in the cell upper electrode 255 is not limited thereto and may be changed in many ways. For example, the cell upper electrode 255 may include a conductive metal nitride, a metal silicide, and combinations thereof.

The first semiconductor chip 10a may include a first upper insulation layer 277 and a second upper insulation layer 279 sequentially stacked on the contact etch stopper 275, a first upper contact plug 261 and a first upper wire 262 disposed on the first upper insulation layer 277, and a second upper contact plug 263 and a second upper wire 264 disposed in the second upper insulation layer 279.

The first upper insulation layer 277 may cover the capacitor DSP. That is, the first upper insulation layer 277 may cover the upper surface and the lateral surface of the capacitor DSP.

In the cell array region CAR, the capacitor DSP may be connected to the first upper wire 262 through the first upper contact plug 261, and the first upper wire 262 may be connected to the second upper wire 264 through the second upper contact plug 263.

The first upper contact plug 261, the first upper wire 262, the second upper contact plug 263, and the second upper wire 264 may include at least one of metal such as copper (Cu), aluminum (Al), tungsten (W), titanium (Ti), or tantalum (Ta), or combinations thereof.

The second chip through via 315 may be disposed in the peripheral circuit region PAR of the cell array structure CS. The second chip through via 315 may penetrate at least a portion of the cell array structure CS.

In detail, the second chip through via 315 may penetrate the first and second upper insulation layers 277 and 279, the contact etch stopper 275, the pad separating insulating layer 273, the contact interlayer insulating layer 271, the cell region shallow trench isolator STI, the bit line etch stopper 171, the first and second lower insulation layers 177 and 173, the spacer insulating layer 175, and the cell array insulating layer 214 and may be connected to one of the second contact pads BP2 in the cell array structure CS disposed in the peripheral circuit region PAR.

A first end of the second chip through via 315 may be connected to the second contact pad BP2, and a second end thereof may be connected to the second chip pad 42 of FIG. 1 of the first semiconductor chip 10a.

Hence, the first chip through via 313 disposed in the peripheral circuit structure PS and the second chip through via 315 disposed in the cell array structure CS may be electrically connected to each other by the contact pad BP.

FIG. 3 shows that the second chip through via 315 is directly connected to the second contact pad BP2, but the connection relationship between the second chip through via 315 and the second contact pad BP2 is not limited thereto and may be changed in many ways. For example, the second chip through via 315 may be electrically connected to the second contact pad BP2 through the lower wire 242 and the lower contact plug 241.

In an embodiment, the width of the second chip through via 315 first direction (X) may be reduced in accordance with a distance to the semiconductor substrate 100 according to the aspect ratio when viewed in cross-section.

A length of the first chip through via 313 in the third direction (Z) may be different from a length of the second chip through via 315 in the third direction (Z). For example, the length of the first chip through via 313 in the third direction (Z) may be less than the length of the second chip through via 315 in the third direction (Z). However, the relationship between the length of the first chip through via 313 in the third direction (Z) and the length of the second chip through via 315 in the third direction (Z) is not limited thereto and may be changed in many ways.

The second chip through via 315 may include a conductive material. For example, the conductive material may include at least one of metals such as aluminum (Al), tungsten (W), titanium (Ti), tantalum (Ta), or copper (Cu), or combinations thereof. However, the conductive material is not limited thereto and may be changed in many ways.

Hence, the first chip through via 313 disposed in the peripheral circuit structure PS may be electrically connected to the second chip through via 315 disposed in the cell array structure CS through the contact pad BP.

According to the semiconductor device 1 according to an embodiment, as the semiconductor chips 10a, 10b, 10c, and 10d in which the peripheral circuit structure PS and the cell array structure CS stacked in the vertical direction are bonded and connected by the contact pad BP are sequentially stacked, and the semiconductor chips 10a, 10b, 10c, and 10d are electrically connected to each other by the chip through vias 313 and 315, an area efficiency and characteristics of the semiconductor device 1 may be improved.

That is, as the peripheral circuit structure PS and the cell array structure CS of the respective semiconductor chips 10a, 10b, 10c, and 10d are stacked in the vertical direction, the sizes (e.g., horizontal dimensions) of the respective semiconductor chips 10a, 10b, 10c, and 10d may be reduced and the characteristics of the respective semiconductor chips 10a, 10b, 10c, and 10d may be improved, compared to the case in which the peripheral circuit structure PS and the cell array structure CS are disposed on the same plane.

Hence, the semiconductor device 1 according to an embodiment may reduce the height of stacking the semiconductor chips 10a, 10b, 10c, and 10d, and reliability of the semiconductor device 1 may be improved.

A semiconductor device according to an embodiment will now be described with reference to FIG. 4 to FIG. 15. In the following embodiments, the same configurations as the above-described embodiments will use the same reference numerals, the repeated descriptions will be omitted or simplified, and the differences will be mainly described.

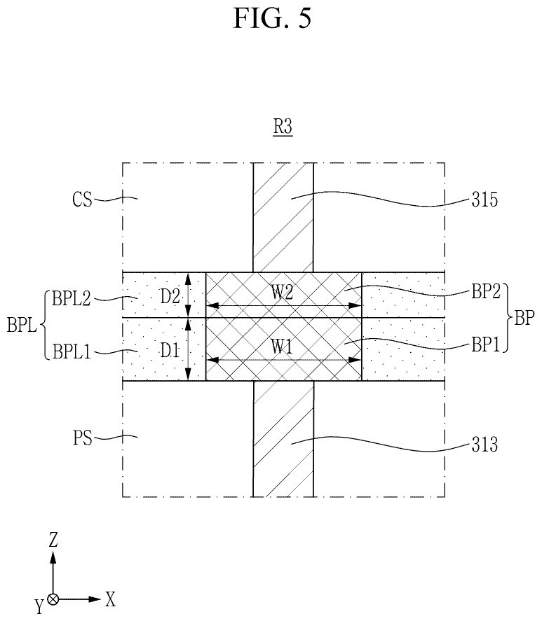

FIG. 4 and FIG. 5 show partially enlarged views of a cross-section of a semiconductor device according to several embodiments. In detail, FIG. 4 and FIG. 5 show partially enlarged views of a region R2 and a region R3 that correspond to a region R1 of FIG. 1.

According to the embodiment shown in FIG. 4, there is a difference in that the width of the first contact pad BP1 is different from the width of the second contact pad BP2, differing from the embodiment shown in FIG. 2 in which the width of the first contact pad BP1 and the width of the second contact pad BP2 are substantially the same.

Referring to FIG. 4, the first width W1 may be different from the second width W2. For example, the first width W1 may be greater than the second width W2. A ratio of the first width W1 to the second width W2 may be about 3:1 to about 7:1. However, the relationship and ratio of the first width W1 and the second width W2 is not limited thereto and may be changed in many ways. For example, the first width W1 may be less than the second width W2.

FIG. 4 shows that the first contact pad BP1 and the second contact pad BP2 are stacked so that a center of the first contact pad BP1 may match a center of the second contact pad BP2, but the disposition relationship of the first contact pad BP1 and the second contact pad BP2 is not limited thereto and may be changed in many ways. For example, the center of the first contact pad BP1 may be disposed to cross the center of the second contact pad BP2. That is, the center of the second contact pad BP2 may be spaced toward a first side or second side of the first direction (X) and/or the second direction (Y) from the center of the first contact pad BP1.

For another example, the second contact pad BP2 may overlap a portion of the first contact pad BP1 in the third direction (Z). That is, a portion of the second contact pad BP2 may be disposed on the first contact pad BP1, and another portion thereof may be disposed on the first contact insulating layer BPL1.

According to the embodiment shown in FIG. 5, there is a difference in that the thickness of the first contact pad BP1 is different from the thickness of the second contact pad BP2.

Referring to FIG. 5, the first thickness D1 may be different from the second thickness D2. For example, the first thickness D1 may be greater than the second thickness D2. A ratio of the first thickness D1 to the second thickness D2 may be about 3:1 to about 7:1. However, the relationship and ratio of the first thickness D1 and the second thickness D2 are not limited thereto and may be changed in many ways. For example, the first thickness D1 may be less than the second thickness D2.

In the present embodiment, the thickness of the first contact insulating layer BPL1 in the third direction (Z) may be different from the thickness of the second contact insulating layer BPL2 in the third direction (Z). That is, the thickness relationship between the first contact insulating layer BPL1 and the second contact insulating layer BPL2 may be substantially the same as the thickness relationship between the first contact pad BP1 and the second contact pad BP2. For example, the thickness of the first contact insulating layer BPL1 may be greater than the thickness of the second contact insulating layer BPL2. However, without being limited thereto, the thickness relationship between the first contact insulating layer BPL1 and the second contact insulating layer BPL2 may be changed in many ways.

Although not shown, in several embodiments, both the width and the thickness of the first contact pad BP1 may be different from both the width and the thickness of the second contact pad BP2. For example, the first width W1 and the first thickness D1 of the first contact pad BP1 may be greater than the second width W2 and the second thickness D2 of the second contact pad BP2, respectively.

According to the semiconductor device according to embodiments shown in FIG. 4 and FIG. 5, at least one of the widths and the thicknesses of the first contact pad BP1 and the second contact pad BP2 are different from each other so that a bonding margin of the first contact pad BP1 and the second contact pad BP2 may be obtained, and the first contact pad BP1 and the second contact pad BP2 may be stably bonded.

At least one of the widths and the thicknesses of the first contact pad BP1 and the second contact pad BP2 is different, so when the semiconductor chips 10a, 10b, 10c, and 10d are stacked, the first contact pad BP1 and the second contact pad BP2 may stably maintain their bonding, and the respective first chip through via 313 and the second chip through via 315 may be stably connected to the first contact pad BP1 and the second contact pad BP2.

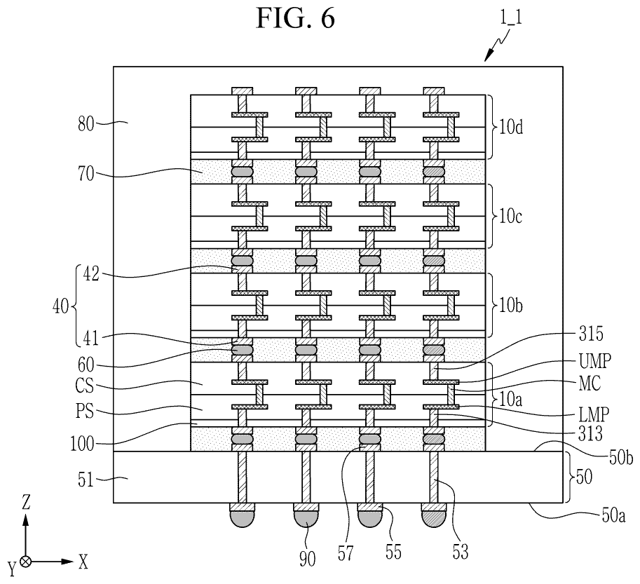

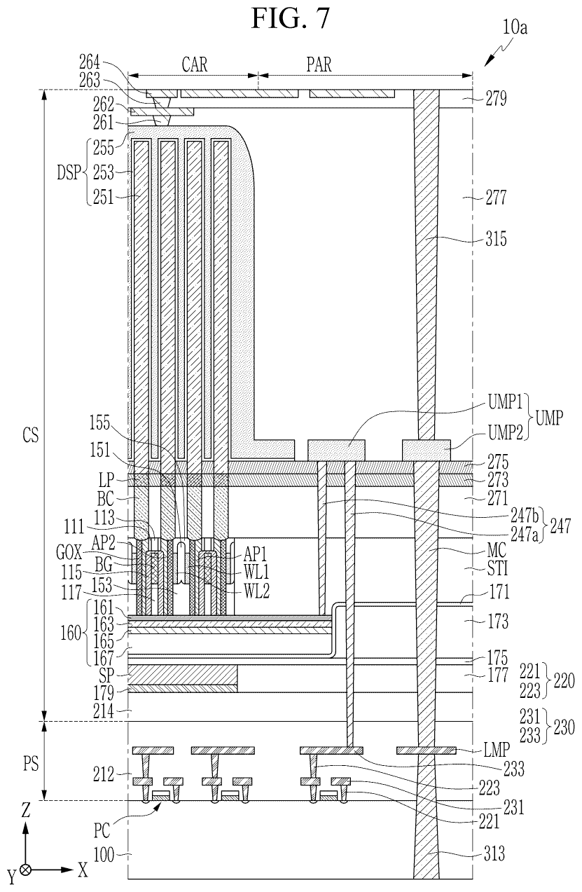

FIG. 6 shows a cross-sectional view of a semiconductor device according to several embodiments. FIG. 7 shows a cross-sectional view of a semiconductor chip included in a semiconductor device according to several embodiments.

Regarding the semiconductor device 1_1 according to an embodiment shown in FIG. 6 and FIG. 7, there is a difference in that the connection of the peripheral circuit structure PS and the cell array structure CS is different in the respective semiconductor chips 10a, 10b, 10c, and 10d included in the semiconductor device 1_1.

The first chip through via 313 disposed in the peripheral circuit structure PS of the respective first to fourth semiconductor chips 10a, 10b, 10c, and 10d included in the semiconductor device 1_1 and the second chip through via 315 disposed in the cell array structure CS may be connected to each other by the upper contact pad UMP, the conductive contact electrode MC, and the lower contact pad LMP.

The first semiconductor chip 10a will now be generally described.

In detail in the present embodiment, referring to FIG. 6 and FIG. 7, the first semiconductor chip 10a may include a lower contact pad LMP disposed in the peripheral circuit structure PS and an upper contact pad UMP disposed in the cell array structure CS.

The lower contact pad LMP and the upper contact pad UMP may be disposed in the peripheral circuit region PAR of the semiconductor substrate 100. However, the positions of the lower contact pad LMP and the upper contact pad UMP are not limited thereto and may be changed in many ways. For example, the lower contact pad LMP and the upper contact pad UMP may be disposed in the cell array region CAR of the semiconductor substrate 100.

The lower contact pad LMP may include the same material as the peripheral circuit wire 230 in the peripheral circuit structure PS, and may be disposed on substantially the same level as the peripheral circuit wire 230. For example, the lower contact pad LMP may include the same material as the second peripheral circuit wire 233 from among the peripheral circuit wire 230, and may be disposed on substantially the same level. For another example, the lower contact pad LMP may include the same material as the first peripheral circuit wire 231 from among the peripheral circuit wire 230, and may be disposed on substantially the same level as the first peripheral circuit wire 231. For another example, the lower contact pad LMP may include a different material from the peripheral circuit wire 230, and may be disposed on a different level from the peripheral circuit wire 230.

In the present embodiment, the first chip through via 313 disposed in the peripheral circuit structure PS may be connected to the lower contact pad LMP. The first chip through via 313 may penetrate at least a portion of the semiconductor substrate 100 and the peripheral circuit insulating layer 212 and may be connected to the bottom surface of the lower contact pad LMP.

The upper contact pad UMP may include the same material as the capacitor DSP and may be disposed on substantially the same level as the capacitor DSP in the cell array structure CS. For example, the upper contact pad UMP may include the same material as the cell upper electrode 255 of the capacitor DSP, and may be disposed on substantially the same level as the protrusion of the cell upper electrode 255. That is, the upper contact pad UMP may be disposed on the contact etch stopper 275.

For another example, the upper contact pad UMP may include the same material as the cell lower electrode 251 of the capacitor DSP, and may be disposed on substantially the same level as the cell lower electrode 251. That is, the upper contact pad UMP may be disposed in the contact etch stopper 275 and on the pad separating insulating layer 273.

For another example, the upper contact pad UMP may include the same material as the landing pad LP, and may be disposed on substantially the same level as the landing pad LP. That is, the upper contact pad UMP may be disposed in the pad separating insulating layer 273.

The upper contact pad UMP may include a first upper contact pad UMP1 connected to the bit line contact plug 247 and a second upper contact pad UMP2 connected to the second chip through via 315 disposed in the cell array structure CS.

In the present embodiment, the bit line contact plug 247 may include a first bit line contact plug 247a for connecting the first upper contact pad UMP1 to the peripheral circuit wire 230 and a second bit line contact plug 247b for connecting the first upper contact pad UMP1 to the bit line BL.

The first bit line contact plug 247a may penetrate the contact interlayer insulating layer 271, the pad separating insulating layer 273, the contact etch stopper 275, the cell region shallow trench isolator STI, the bit line etch stopper 171, the first lower insulation layer 177, the spacer insulating layer 175, the second lower insulation layer 173, and the cell array insulating layer 214, and may be connected to the second peripheral circuit wire 233 from among the peripheral circuit wire 230.

The second bit line contact plug 247b may penetrate the contact interlayer insulating layer 271, the pad separating insulating layer 273, the contact etch stopper 275, and the cell region shallow trench isolator STI, and may be connected to the polysilicon layer 161 of the bit line BL. However, without being limited thereto, the second bit line contact plug 247b may be connected to one of the first metal layer 163 and the second metal layer 165 of the bit line BL.

The peripheral circuit wire 230 of the peripheral circuit structure PS and/or the peripheral circuit PC and the bit line BL of the cell array structure CS may be electrically connected to each other by the first bit line contact plug 247a and the second bit line contact plug 247b connected to the first upper contact pad UMP1. However, the connection relationship between the bit line BL and the peripheral circuit structure PS is not limited thereto and may be changed in many ways.

In the present embodiment, the widths of the first bit line contact plug 247a and the second bit line contact plug 247b in the first direction (X) may be reduced in accordance with a distance to the semiconductor substrate 100 according to the aspect ratio on a cross-section. For example, the first bit line contact plug 247a and the second bit line contact plug 247b may narrow as they approach the semiconductor substrate 100.

In the present embodiment, the second chip through via 315 disposed in the cell array structure CS may be connected to the second upper contact pad UMP.

The second chip through via 315 may penetrate at least a portion of the cell array structure CS and may be connected to the upper surface of the second upper contact pad UMP2. That is, the second chip through via 315 may penetrate the first and second upper insulation layers 277 and 279 and may be connected to the second upper contact pad UMP2.

In the present embodiment, the first semiconductor chip 10a may include a conductive contact electrode MC for connecting the lower contact pad LMP to the second upper contact pad UMP2.

The conductive contact electrode MC may penetrate a portion of the peripheral circuit structure PS and a portion of the cell array structure CS. That is, the conductive contact electrode MC may extend in the third direction (Z) to reach the cell array structure CS from the peripheral circuit structure PS. In other words, a portion of the conductive contact electrode MC may be disposed in the peripheral circuit structure PS, and another portion thereof may be disposed in the cell array structure CS.

The conductive contact electrode MC may penetrate some or all of the contact interlayer insulating layer 271, the pad separating insulating layer 273, the contact etch stopper 275, the cell region shallow trench isolator STI, the bit line etch stopper 171, the first lower insulation layer 177, the spacer insulating layer 175, the second lower insulation layer 173, and the cell array insulating layer 214 and may be connected to the lower contact pad LMP.

In the present embodiment, the width of the conductive contact electrode MC in the first direction (X) may be reduced in accordance with a distance to the semiconductor substrate 100 according to the aspect ratio on a cross-section. For example, the conductive contact electrode MC may narrow as it approaches the semiconductor substrate 100.

In the present embodiment, the first chip through via 313 connected to the lower contact pad LMP disposed in the peripheral circuit structure PS and the second chip through via 315 connected to the second upper contact pad UMP2 disposed in the cell array structure CS may be electrically connected to each other through the conductive contact electrode MC. However, the connection relationship between the first chip through via 313 and the second chip through via 315 is not limited thereto and may be changed in many ways. For example, the first chip through via 313 may be electrically connected to the conductive contact electrode MC when connected to the peripheral circuit wire 230 disposed in the peripheral circuit structure PS.

Although not shown in FIG. 7, the first semiconductor chip 10a according to several embodiments may further include a word line contact plug for connecting the word lines WL1 and WL2 to the peripheral circuit structure PS and a contact pad that is not the first upper contact pad UMP1 and the second upper contact pad UMP2.

Although not shown in FIG. 7, in several embodiments, the first semiconductor chip 10a may further include a capacitor contact plug for connecting the capacitor DSP to the peripheral circuit structure PS. For example, the capacitor contact plug may further include a first capacitor contact plug for connecting the second upper wire 264 to the capacitor DSP and a second capacitor contact plug for connecting the second upper wire 264 to components of the peripheral circuit structure PS.

For another example, it may further include a capacitor contact plug (not shown) for connecting the capacitor DSP to the peripheral circuit structure PS and a contact pad (not shown) that is not the first upper contact pad UMP1 and the second upper contact pad UMP2.

The first semiconductor chip 10a has been generally described in the present embodiment, and the description of the first semiconductor chip 10a may be applied to the second to fourth semiconductor chips 10b, 10c, and 10d.

The first to fourth semiconductor chips 10a, 10b, 10c, and 10d are shown to be the same in the present embodiment, and some of the first to fourth semiconductor chips 10a, 10b, 10c, and 10d may have the configuration of the semiconductor chip shown in FIG. 3 and others thereof may have the configuration of the semiconductor chip shown in FIG. 7 in several embodiments.

The semiconductor device 1_1 shown in FIG. 6 and FIG. 7 may have substantially the same effect as the semiconductor device 1 according to an embodiment.

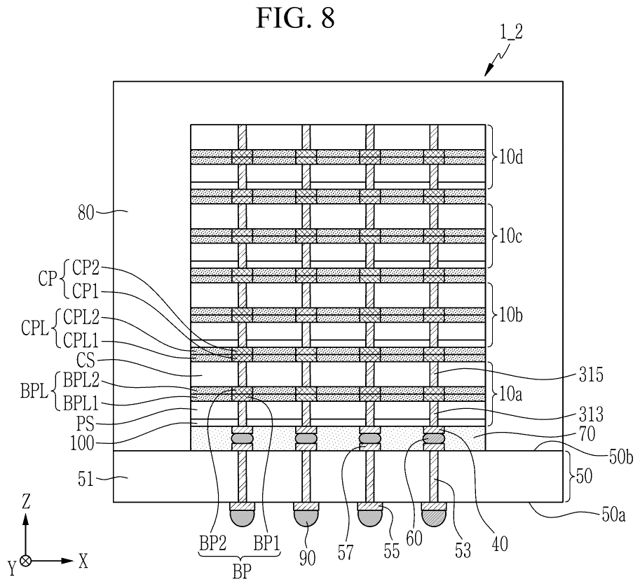

FIG. 8 shows a cross-section of a semiconductor device according to several embodiments.

The semiconductor device 1_2 shown in FIG. 8 is different from the semiconductor device 1 according to an embodiment in that the method for connecting the first to fourth semiconductor chips 10a, 10b, 10c, and 10d is different.

In detail, referring to FIG. 8, the chip bonding pad CP and the chip bonding insulating layer CPL may be disposed between adjacent semiconductor chips among the first to fourth semiconductor chips 10a, 10b, 10c, and 10d

That is, the chip bonding pad CP and the chip bonding insulating layer CPL may be disposed between the first semiconductor chip 10a and the second semiconductor chip 10b, between the second semiconductor chip 10b and the third semiconductor chip 10c, and between the third semiconductor chip 10c and the fourth semiconductor chip 10d.

The chip bonding pad CP may include a first chip bonding pad CP1 disposed on the second surfaces of the first semiconductor chip 10a, the second semiconductor chip 10b, and the third semiconductor chip 10c, and a second chip bonding pad CP2 disposed on the first surfaces of the second semiconductor chip 10b, the third semiconductor chip 10c, and the fourth semiconductor chip 10d.

The chip bonding insulating layer CPL may include a first chip bonding insulating layer CPL1 surrounding a lateral surface of the first chip bonding pad CP1 and a second chip bonding insulating layer CPL2 surrounding a lateral surface of the second chip bonding pad CP2.

In the present embodiment, the first chip bonding pad CP1 and the first chip bonding insulating layer CPL1 may be respectively bonded and connected to the second chip bonding pad CP2 and the second chip bonding insulating layer CPL2 to configure a bonding surface. That is, the first chip bonding pad CP1 may contact the second chip bonding pad CP2 to configure a bonding surface, and the first chip bonding insulating layer CPL1 may contact the second chip bonding insulating layer CPL2 to configure a bonding surface.

In the present embodiment, the first chip bonding pad CP1 and the first chip bonding insulating layer CPL1 may be respectively combined and bonded to the second chip bonding pad CP2 and the second chip bonding insulating layer CPL2, respectively, by a chip hybrid bonding or direct bonding. However, the method for respectively bonding the first chip bonding pad CP1 and the first chip bonding insulating layer CPL1 to the second chip bonding pad BP2 and the second chip bonding insulating layer CPL2 is not limited thereto and may be changed in many ways.

An upper surface of the first chip bonding pad CP1 and an upper surface of the first chip bonding insulating layer CPL1 may be coplanar and may be disposed on substantially the same level as each other. A bottom surface of the second chip bonding pad CP2 and a bottom surface of the second chip bonding insulating layer CPL2 may be coplanar and may be disposed on substantially the same level as each other.

As the chip bonding pad CP and the chip bonding insulating layer CPL are disposed between adjacent semiconductor chips among the first to fourth semiconductor chips 10a, 10b, 10c, and 10d, the first chip through via 313 of one of the first to fourth semiconductor chips 10a, 10b, 10c, and 10d may be connected to the second chip bonding pad CP2, and the second chip through via 315 may be connected to the first chip bonding pad CP1.

As the chip bonding pad CP and the chip bonding insulating layer CPL are disposed between adjacent semiconductor chips among the first to fourth semiconductor chips 10a, 10b, 10c, and 10d, the first chip through via 313 of one of the first to fourth semiconductor chips 10a, 10b, 10c, and 10d may be electrically connected to the second chip through via 315 of another one of the first to fourth semiconductor chips by the chip bonding pad CP.

For example, the first chip through via 313 of the second semiconductor chip 10b may be electrically connected to the second chip through via 315 of the first semiconductor chip 10a through the chip bonding pad CP, and the second chip through via 315 of the second semiconductor chip 10b may be electrically connected to the first chip through via 313 of the third semiconductor chip 10c through the chip bonding pad CP.

In the present embodiment, the first chip bonding pad CP1 and the second chip bonding pad CP2 may respectively include a conductive material such as copper (Cu), tungsten (W) nickel (Ni), gold (Au), or silver (Ag). For example, the first chip bonding pad CP1 and second chip bonding pad CP2 may respectively include copper (Cu). However, the material included in the first chip bonding pad CP1 and the second chip bonding pad CP2 is not limited thereto and may be changed in many ways.

The first chip bonding insulating layer CPL1 and the second chip bonding insulating layer CPL2 may respectively include an insulating material such as a silicon oxide (SiO) and a silicon carbonitride (SiCN). For example, the first chip bonding insulating layer CPL1 and the second chip bonding insulating layer CPL2 may respectively include a silicon carbonitride (SiCN). However, the material included in the first chip bonding insulating layer CPL1 and the second chip bonding insulating layer CPL2 is not limited thereto and may be changed in many ways.

In the present embodiment, the first semiconductor chip 10a disposed on a lowermost end from among the first to fourth semiconductor chips 10a, 10b, 10c, and 10d may be electrically connected to the package substrate 50 by the chip connecting terminal 60. That is, the first semiconductor chip 10a may be electrically connected to the package substrate 50 by the chip connecting terminal 60 disposed between the chip pad 40 disposed on the first surface of the first semiconductor chip 10a and the second substrate pad 57 disposed on the second surface 50b of the package substrate 50. However, the method for connecting the first semiconductor chip 10a to the package substrate 50 is not limited thereto and may be changed in many ways. For example, the chip bonding pad CP and the chip bonding insulating layer CPL may be further disposed between the first semiconductor chip 10a and the package substrate 50, and the first semiconductor chip 10a and the package substrate 50 may be connected and bonded to each other by the chip bonding pad CP.

The semiconductor device 1_2 according to the embodiment shown in FIG. 8 may have substantially the same effect as the semiconductor device 1 according to an embodiment. In addition to this, as the chip connecting terminal 60 disposed between adjacent semiconductor chips among the first to fourth semiconductor chips 10a, 10b, 10c, and 10d is omitted, the total stacking height of the first to fourth semiconductor chips 10a, 10b, 10c, and 10d may be reduced and area efficiency may be improved.

The first to fourth semiconductor chips 10a, 10b, 10c, and 10d may be flexibly bent while performing the hybrid bonding so bonding defects may be prevented from being generated between adjacent semiconductor chips among the first to fourth semiconductor chips 10a, 10b, 10c, and 10d, and stresses may not be provided to the bonded first to fourth semiconductor chips 10a, 10b, 10c, and 10d during a subsequent process for performing a thermal process.

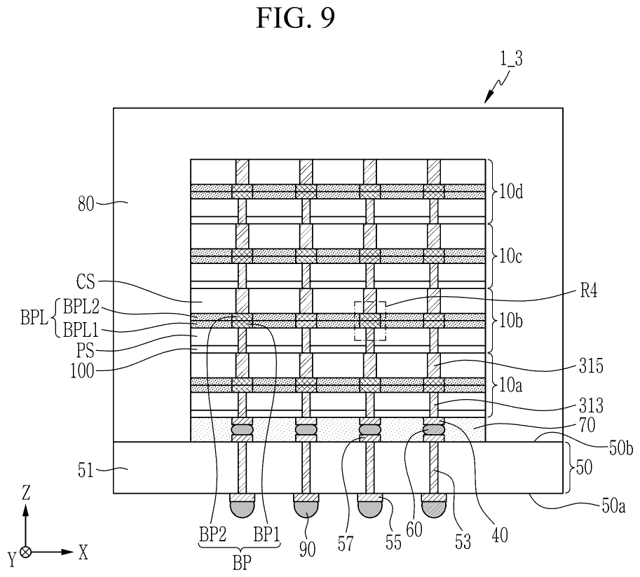

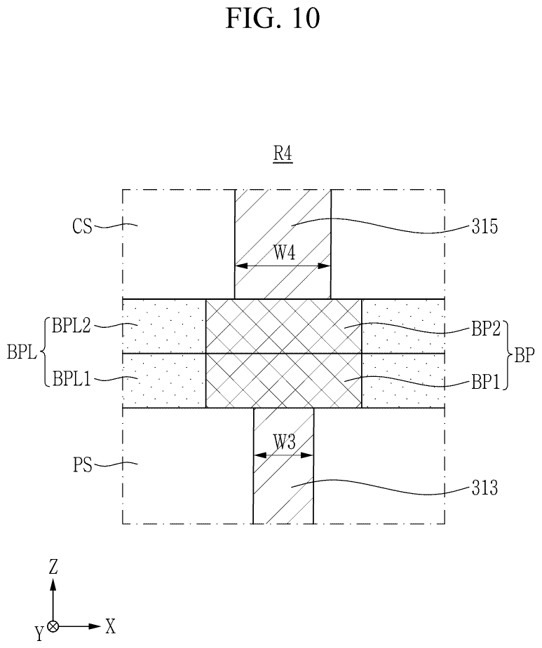

FIG. 9 shows a cross-section of a semiconductor device according to several embodiments. FIG. 10 shows a partially enlarged view of a region R4 of FIG. 9.

The semiconductor device 1_3 shown in FIG. 9 and FIG. 10 is different from the semiconductor device 1 according to an embodiment in that the methods for connecting the respective first to fourth semiconductor chips 10a, 10b, 10c, and 10d are different.

Referring to FIG. 9 and FIG. 10, in the present embodiment, the first to fourth semiconductor chips 10a, 10b, 10c, and 10d may be electrically connected to the first chip through via 313 by the second chip through via 315.

In detail, the first chip through via 313 of one of the first to fourth semiconductor chips 10a, 10b, 10c, and 10d may be directly connected to the second chip through via 315 of another thereof. For example, the bottom surface of the first chip through via 313 of the second semiconductor chip 10b may contact the upper surface of the second chip through via 315 of the first semiconductor chip 10a, and the upper surface of the second chip through via 315 of the second semiconductor chip 10b may contact the bottom surface of the first chip through via 313 of the third semiconductor chip 10c.

FIG. 9 shows that respective terminals of the first chip through via 313 and the second chip through via 315 disposed on the first to fourth semiconductor chips 10a, 10b, 10c, and 10d are coplanar with the first surface and the second surface of the first to fourth semiconductor chips 10a, 10b, 10c, and 10d, but the inventive concept is not limited thereto. For example, the first chip through via 313 may protrude from the respective first surfaces of the first to fourth semiconductor chips 10a, 10b, 10c, and 10d, or the second chip through via 315 may protrude from the respective second surfaces of the first to fourth semiconductor chips 10a, 10b, 10c, and 10d. For another example, the terminals of both the first chip through via 313 and the second chip through via 315 may protrude from the respective first surfaces and the second surfaces of the first to fourth semiconductor chips 10a, 10b, 10c, and 10d.

In the present embodiment, the first surface of one of the first to fourth semiconductor chips 10a, 10b, 10c, and 10d may contact the second surface of another thereof. For example, the first surface of the second semiconductor chip 10b may contact the second surface of the first semiconductor chip 10a, and the second surface of the second semiconductor chip 10b may contact the first surface of the third semiconductor chip 10c. However, the disposition relationship of the first to fourth semiconductor chips 10a, 10b, 10c, and 10d is not limited thereto and may be changed in many ways. For example, the first surface of one of the first to fourth semiconductor chips 10a, 10b, 10c, and 10d may be spaced from the second surface of another thereof in the third direction (Z).

That is, as described above, when the first chip through via 313 protrudes from the respective first surfaces of the first to fourth semiconductor chips 10a, 10b, 10c, and 10d, or the second chip through via 315 protrudes from the respective second surfaces of the first to fourth semiconductor chips 10a, 10b, 10c, and 10d, the respective first to fourth semiconductor chips 10a, 10b, 10c, and 10d may be spaced from each other.

Referring to FIG. 10, in the present embodiment, the widths of the first chip through via 313 and the second chip through via 315 in the first direction (X) disposed on the respective first to fourth semiconductor chips 10a, 10b, 10c, and 10d may be different from each other. That is, the first chip through via 313 may have the first width W3 in the first direction (X), the second chip through via 315 may have the second width W4 in the first direction (X), and the first width W3 may be different from the second width W4. For example, the first width W3 may be less than the second width W4. However, the relationship of the first width W3 and the second width W4 are not limited thereto and may be changed in many ways. For example, the first width W3 may be greater than the second width W4.

As described above, when the first chip through via 313 and the second chip through via 315 have different widths, a margin for connecting the first chip through via 313 to the second chip through via 315 may be obtained, and they may be stably connected to each other.

The semiconductor device 1_3 according to the embodiment shown in FIG. 9 and FIG. 10 may have substantially the same effect as the semiconductor device 1 according to an embodiment.

In addition to this, the chip connecting terminal 60 disposed among the first to fourth semiconductor chips 10a, 10b, 10c, and 10d may be omitted, and the chip through vias 313 and 315 may be directly connected, thereby reducing the total stacking height of the first to fourth semiconductor chips 10a, 10b, 10c, and 10d and improving the area efficiency.

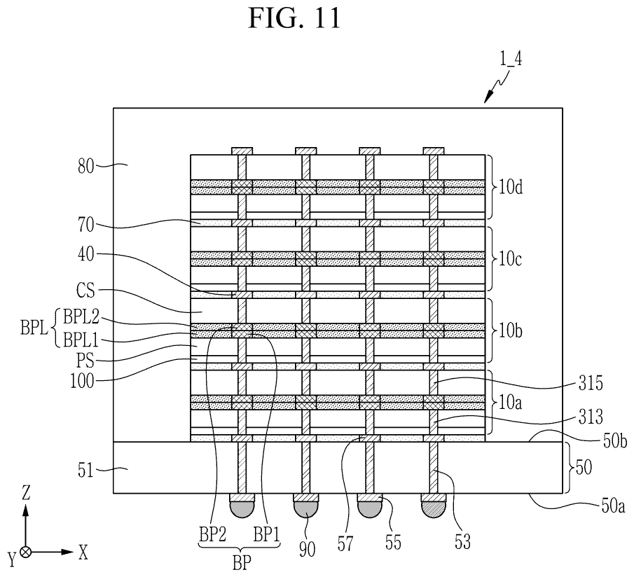

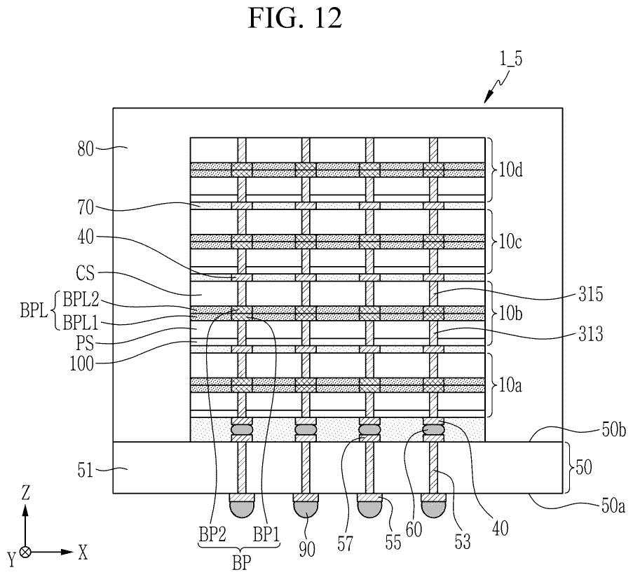

FIG. 11 and FIG. 12 show cross-sections of a semiconductor device according to several embodiments.

The semiconductor devices 1_4 and 1_5 shown in FIG. 11 and FIG. 12 are different from the semiconductor device 1 according to an embodiment in that the methods for respectively connecting the first to fourth semiconductor chips 10a, 10b, 10c, and 10d are different.

Referring to FIG. 11 and FIG. 12, the first to fourth semiconductor chips 10a, 10b, 10c, and 10d may be electrically connected to the first chip through via 313 and the second chip through via 315 of adjacent semiconductor chips by the chip pad 40.

In the present embodiment, the chip pad 40 may be disposed on one or both of the first surfaces and the second surfaces of the first to fourth semiconductor chips 10a, 10b, 10c, and 10d.

According to an embodiment shown in FIG. 11, the chip pad 40 may be disposed not on the first surfaces of the first to fourth semiconductor chips 10a, 10b, 10c, and 10d but on the second surfaces thereof.

According to an embodiment shown in FIG. 12, the chip pad 40 may be disposed on the first surfaces of the first to fourth semiconductor chips 10a, 10b, 10c, and 10d and not on the second surfaces thereof.

Hence, the chip pad 40 may be disposed between adjacent semiconductor chips among the first to fourth semiconductor chips 10a, 10b, 10c, and 10d. The underfill member 70 may be disposed between adjacent semiconductor chips among the first to fourth semiconductor chips 10a, 10b, 10c, and 10d, and may surround the chip pad 40.

According to embodiments shown in FIG. 11 and FIG. 12, the first chip through via 313 of one of the first to fourth semiconductor chips 10a, 10b, 10c, and 10d and the second chip through via 315 of another thereof may be electrically connected to each other by the chip pad 40. That is, the upper surface of the chip pad 40 may be connected to the first chip through via 313 of one of the first to fourth semiconductor chips 10a, 10b, 10c, and 10d, and the second chip through via 315 of another may be connected to the bottom surface of the chip pad 40.

Hence, the first to fourth semiconductor chips 10a, 10b, 10c, and 10d may be electrically connected by the chip pad 40.

According to the semiconductor device 1_4 according to an embodiment shown in FIG. 11, as the chip pad 40 is not disposed on the first surface of the first semiconductor chip 10a disposed on the lowermost end from among the first to fourth semiconductor chips 10a, 10b, 10c, and 10d, the first semiconductor chip 10a and the package substrate 50 may be electrically connected to each other by the second substrate pad 57.

That is, the first chip through via 313 of the first semiconductor chip 10a may be directly connected to the second substrate pad 57 of the package substrate 50. The underfill member 70 may be disposed between the first semiconductor chip 10a and the package substrate 50, and may surround the second substrate pad 57. However, the method for connecting the first semiconductor chip 10a to the package substrate 50 is not limited thereto and may be changed in many ways. For example, as the chip pad 40 and the chip connecting terminal 60 are further disposed between the first surface of the first semiconductor chip 10a and the second substrate pad 57 of the package substrate 50, the first semiconductor chip 10a and the package substrate 50 may be electrically connected to each other by the chip connecting terminal 60, as shown in FIG. 12.

The semiconductor devices 1_4 and 1_5 according to the embodiment shown in FIG. 11 and FIG. 12 may have substantially the same effect as the semiconductor device 1 according to an embodiment.

In addition to this, the chip connecting terminal 60 disposed among the first to fourth semiconductor chips 10a, 10b, 10c, and 10d may be omitted, and the chip through vias 313 and 315 may be connected to the chip pad 40, thereby reducing the total stacking height of the first to fourth semiconductor chips 10a, 10b, 10c, and 10d and improving the area efficiency.

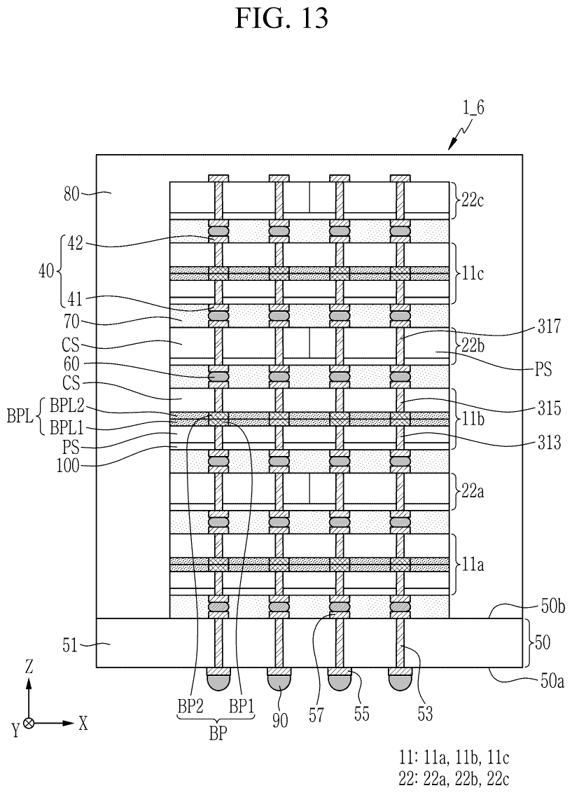

FIG. 13 to FIG. 15 show cross-sections of a semiconductor device according to several embodiments.

The semiconductor devices 1_6, 1_7, and 1_8 shown in FIG. 13 to FIG. 15 are different from the semiconductor device 1 according to an embodiment in that the semiconductor devices 1_6, 1_7, and 1_8 include a first type semiconductor chip 11 (e.g., a cell-on-peripheral semiconductor chip) and a second type semiconductor chip 22 (e.g., a cell-adjacent-to-peripheral semiconductor chip) having different structures. In the cell-on-peripheral semiconductor chip, the cell array structure CS is on the peripheral circuit structure PS, while in the cell-adjacent-to-peripheral semiconductor chip, the cell array structure CS is next to the peripheral circuit structure PS in a horizontal direction.

Regarding the semiconductor devices 1_6, 1_7, and 1_8 shown in FIG. 13 to FIG. 15, the first type semiconductor chip 11 may include first to fourth semiconductor chips 11a, 11b, 11c, and 11d.

The respective first to fourth semiconductor chips 11a, 11b, 11c, and 11d of the first type semiconductor chip 11 may be substantially the same as the first to fourth semiconductor chips 10a, 10b, 10c, and 10d described with reference to FIG. 1 to FIG. 3. However, without being limited thereto, in several embodiments, the first type semiconductor chip 11 may be substantially the same as the first to fourth semiconductor chips 10a, 10b, 10c, and 10d described with reference to FIG. 6. The previously-provided description may be applied to this so it will be omitted.

The second type semiconductor chip 22 may include first to third semiconductor chips 22a, 22b, and 22c.

The respective first to fourth semiconductor chips 22a, 22b, 22c, and 22d of the second type semiconductor chip 22 may include a semiconductor substrate 100, a peripheral circuit structure PS, and a cell array structure CS, and the peripheral circuit structure PS and the cell array structure CS may be disposed on the same plane on the semiconductor substrate 100, differing from the first type semiconductor chip 11. That is, the peripheral circuit structure PS and the cell array structure CS of the second type semiconductor chip 22 may be disposed in parallel with each other on the semiconductor substrate 100. For example, the peripheral circuit structure PS and the cell array structure CS of the second type semiconductor chip 22 may be horizontally disposed next to each other, or side by side.

FIG. 13 to FIG. 15 show that the peripheral circuit structure PS and the cell array structure CS are disposed in parallel, but the disposition relationship of the peripheral circuit structure PS and the cell array structure CS is not limited thereto and may be changed in many ways. For example, the peripheral circuit structure PS may be disposed near at least one of a first side and a second side of the cell array structure CS in the first direction (X) and at least one of a first side and a second side thereof in the second direction (Y) in a plan view. For another example, the peripheral circuit structure PS may surround the cell array structure CS in a plan view.

The second type semiconductor chip 22 may include a third chip through via 317 penetrating at least a portion of the respective first to fourth semiconductor chips 22a, 22b, 22c, and 22d. The third chip through via 317 may be disposed in the peripheral circuit structure PS and the cell array structure CS, respectively. However, the position of the third chip through via 317 is not limited thereto and may be changed in many ways. For example, the third chip through via 317 may be disposed in one of the peripheral circuit structure PS and the cell array structure CS but not in the other.

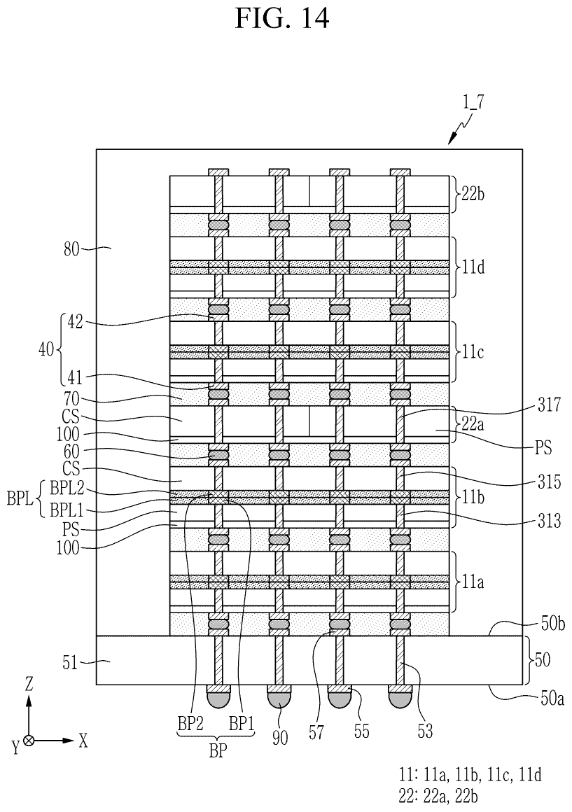

Referring to FIG. 13 and FIG. 14, the chip pad 40 may be respectively disposed on a first surface and a second surface of the first type semiconductor chip 11 and a first surface and a second surface of the second type semiconductor chip 22.

The chip pad 40 may include a first chip pad 41 disposed on the first surfaces of the first type semiconductor chip 11 and the second type semiconductor chip 22 and a second chip pad 42 disposed on the second surfaces of the first type semiconductor chip 11 and the second type semiconductor chip 22.

In detail, regarding the semiconductor device 1_6 shown in FIG. 13, the first type semiconductor chip 11 and the second type semiconductor chip 22 may be alternately stacked in the third direction (Z) on the second surface 50b of the package substrate 50.

That is, the first semiconductor chip 11a of the first type semiconductor chip 11, the first semiconductor chip 22a of the second type semiconductor chip 22, the second semiconductor chip 11b of the first type semiconductor chip 11, the second semiconductor chip 22b of the second type semiconductor chip 22, the third semiconductor chip 11c of the first type semiconductor chip 11, and the third semiconductor chip 22c of the second type semiconductor chip 22 may be sequentially stacked in that order.

According to the embodiment shown in FIG. 13, the chip connecting terminal 60 may be disposed between the respective first type semiconductor chip 11 and the second type semiconductor chip 22. The first type semiconductor chip 11 and the second type semiconductor chip 22 may be electrically connected by the chip connecting terminal 60.

The chip connecting terminal 60 may be disposed between the first chip pad 41 and the second chip pad 42. That is, the chip connecting terminal 60 may be disposed between the first chip pad 41 of one of the first type semiconductor chips 11 and the second chip pad 42 of one of the second type semiconductor chips 22.

The respective first chip through via 313 and the second chip through via 315 of the first type semiconductor chip 11 may be electrically connected to the third chip through via 317 of one of the second type semiconductor chips 22 and the third chip through via 317 of another of the second type semiconductor chips 22 by the chip connecting terminal 60.

That is, the respective first chip through via 313 and the second chip through via 315 of the first type semiconductor chip 11 may be electrically connected to the third chip through via 317 of one of the second type semiconductor chips 22 and the third chip through via 317 of another of the second type semiconductor chips 22 through the chip pad 40 and the chip connecting terminal 60.

For example, the first chip through via 313 disposed in the second semiconductor chip 11b of the first type semiconductor chip 11 may be electrically connected to the third chip through via 317 disposed in the first semiconductor chip 22a of the second type semiconductor chip 22 through the chip pad 40 and the chip connecting terminal 60.

The second chip through via 315 disposed in the second semiconductor chip 11b of the first type semiconductor chip 11 may be electrically connected to the third chip through via 317 disposed in the second semiconductor chip 22b of the second type semiconductor chip 22 through the chip pad 40 and the chip connecting terminal 60.

FIG. 13 shows that the first type semiconductor chip 11 and the second type semiconductor chip 22 respectively include three semiconductor chips, but the number of the semiconductor chips respectively included by the first type semiconductor chip 11 and the second type semiconductor chip 22 is not limited thereto and may be changed in many ways. For example, the respective first type semiconductor chip 11 and the second type semiconductor chip 22 may each include two, four, or equal to or more than five semiconductor chips. For another example, the respective first type semiconductor chip 11 and the second type semiconductor chip 22 may each include a number of semiconductor chips equal to a multiple of four.

The semiconductor device 1_7 shown in FIG. 14 is different from the semiconductor device 1_6 shown in FIG. 13 in that the number of the first type semiconductor chip 11 and the number of the second type semiconductor chip 22 and their stacking orders are different.

Referring to FIG. 14, regarding the semiconductor device 1_7 according to the present embodiment, the number of the first type semiconductor chip 11 may be different from the number of the second type semiconductor chip 22. In the present embodiment, the number of the first type semiconductor chips 11 may be greater than the number of the second type semiconductor chips 22. For example, the first type semiconductor chip 11 may include first to fourth semiconductor chips 11a, 11b, 11c, and 11d, and the second type semiconductor chip 22 may include first and second semiconductor chips 22a and 22b. However, this is an example, and in several embodiments, the number of the second type semiconductor chips 22 may be greater than the number of the first type semiconductor chips 11.

In the present embodiment, the semiconductor device 1_7 may have a stacking structure in which the first type semiconductor chips 11 are repeatedly stacked and the second type semiconductor chip 22 may be alternately stacked in the third direction (Z). That is, a stacking unit including the continuously stacked first type semiconductor chips 11 and the second type semiconductor chip 22 stacked on them may be repeatedly stacked on the second surface 50b of the package substrate 50.

For example, the first semiconductor chip 11a of the first type semiconductor chip 11, the second semiconductor chip 11b of the first type semiconductor chip 11, the first semiconductor chip 22a of the second type semiconductor chip 22, the third semiconductor chip 11c of the first type semiconductor chip 11, the fourth semiconductor chip 11d of the first type semiconductor chip 11, and the second semiconductor chip 22b of the second type semiconductor chip 22 may be sequentially stacked on the package substrate 50 in that order. However, the number and the stacking order of the semiconductor chips included in the first and second semiconductor types 11 and 22 are not limited thereto and may be changed in many ways. For example, a stacking unit including at least three repeatedly stacked first type semiconductor chips 11 and at least two repeatedly stacked second type semiconductor chips 22 may be repeatedly stacked on the package substrate 50. For another example, the first type semiconductor chip 11 may be continuously stacked, and the second type semiconductor chip 22 may be continuously stacked thereon. For another example, the second type semiconductor chip 22 may be continuously stacked, and the first type semiconductor chip 11 may be continuously stacked thereon.

As shown in FIG. 14, when the first type semiconductor chip 11 is repeatedly stacked, the first chip through via 313 of one of the first type semiconductor chips 11 may be electrically connected to the second chip through via 315 of another one of the first type semiconductor chips 11 by the chip pad 40 and the chip connecting terminal 60.

The semiconductor devices 1_6 and 1_7 according to the embodiment shown in FIG. 13 and FIG. 14 may have substantially the same effect as the semiconductor device 1 according to an embodiment.

In addition to this, as it includes the first type semiconductor chip 11 and the second type semiconductor chip 22 having different configurations, the stacking structure and the stacking height of the semiconductor device may be varied according to characteristics and purposes of the semiconductor devices 1_6 and 1_7.

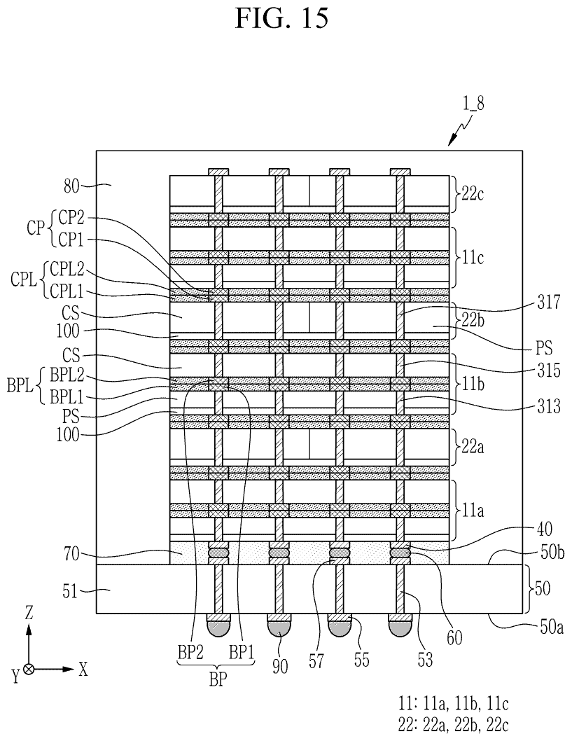

The semiconductor device 1_8 shown in FIG. 15 is different from the semiconductor device 1_6 shown in FIG. 13 in that the methods for connecting the first type semiconductor chip 11 to the second type semiconductor chip 22 are different.

In detail, referring to FIG. 15, the chip bonding pad CP and the chip bonding insulating layer CPL may be disposed between the respective first type semiconductor chip 11 and the second type semiconductor chip 22.

The chip bonding pad CP, the chip bonding insulating layer CPL, and their bonding methods are substantially the same as the description given with reference to FIG. 8, of which the detailed description will be omitted.

As the chip bonding pad CP and the chip bonding insulating layer CPL are disposed between the respective first type semiconductor chip 11 and the second type semiconductor chip 22, the first chip through via 313 of the first type semiconductor chip 11 may be connected to the second chip bonding pad CP2, and the second chip through via 315 may be connected to the first chip bonding pad CP1.

A first end of the third chip through via 317 of the second type semiconductor chip 22 may be connected to the first chip bonding pad CP1, and a second end thereof may be connected to the second chip bonding pad CP2.

Hence, the first and second chip through vias 313 and 315 of the first type semiconductor chip 11 may be electrically connected to the third chip through via 317 of the second type semiconductor chip 22 by the contact pad BP.

The semiconductor device 1_8 according to the embodiment shown in FIG. 15 may have substantially the same effect as the semiconductor device 1_6 shown in FIG. 13.

In addition to this, the chip connecting terminal 60 between the first type semiconductor chip 11 and the second type semiconductor chip 22 is omitted, thereby reducing the stacking height of the semiconductor device 1_8 and improving the area efficiency.

Also, the flexible bending may be generated while performing a hybrid bonding so the bonding defect may be prevented from being generated between the first type semiconductor chip 11 and the second type semiconductor chip 22, and the stress may be prevented from being applied to the first type semiconductor chip 11 and the second type semiconductor chip 22 bonded during the process for performing a subsequent thermal process.

While this disclosure has been described in connection with what is presently considered to be practical embodiments, it is to be understood that the disclosure is not limited to the disclosed embodiments and/or the examples, but, on the contrary, is intended to cover various modifications and equivalent arrangements included within the spirit and scope of the inventive concept.

What is claimed is:

1. A semiconductor device comprising:
a package substrate; and
semiconductor chips stacked on the package substrate,
wherein each of the semiconductor chips respectively includes:
a semiconductor substrate,
a peripheral circuit structure and a cell array structure disposed to overlap each other in a vertical direction on the semiconductor substrate,
a first contact pad in the peripheral circuit structure,
a second contact pad in the cell array structure, the second contact pad being connected to the first contact pad,
a first chip through via penetrating at least a portion of the semiconductor substrate and the peripheral circuit structure, the first chip through via being connected to the first contact pad, and
a second chip through via penetrating at least a portion of the cell array structure, the second chip through via being connected to the second contact pad, and
wherein the first chip through via of a first semiconductor chip of the semiconductor chips is connected to the second chip through via of a second semiconductor chip of the semiconductor chips.

2. The semiconductor device of claim 1, wherein for each semiconductor chip:
the peripheral circuit structure is between the semiconductor substrate and the cell array structure.

3. The semiconductor device of claim 2, wherein for each semiconductor chip, the first contact pad contacts the second contact pad, and
wherein each semiconductor chip further includes:
a first contact insulating layer surrounding the first contact pad; and
a second contact insulating layer surrounding the second contact pad and contacting the first contact insulating layer.

4. The semiconductor device of claim 3, wherein for each semiconductor chip:
the first contact pad is directly connected to the first chip through via, and
the second contact pad is directly connected to the second through via.

5. The semiconductor device of claim 4, wherein for each semiconductor chip:
the first contact pad and the second contact pad include copper (Cu), and
the first contact insulating layer and the second contact insulating layer include at least one of a silicon oxide (SiO) and a silicon carbonitride (SiCN).

6. The semiconductor device of claim 3, wherein
a width of the first contact pad is different from a width of the second contact pad or a thickness of the first contact pad is different from a thickness of the second contact pad.

7. The semiconductor device of claim 3, wherein
the first chip through via of the first semiconductor chip and the second chip through via have different widths, and
the first chip through via of the first semiconductor chip is directly connected to the second chip through via of the second semiconductor chip.

8. The semiconductor device of claim 3, further comprising:
a chip pad between the semiconductor chips,
wherein the first chip through via of the first semiconductor chip and the second chip through via of the second semiconductor chip are connected to the chip pad.

9. The semiconductor device of claim 8, wherein:
the semiconductor chips respectively include:
a first surface and a second surface opposite to each other, and
the chip pad is on at least one of the first surface and the second surface of at least one of the semiconductor chips.

10. The semiconductor device of claim 9, wherein
the chip pad includes:
a first chip pad on the first surface;
a second chip pad on the second surface; and
a chip connecting terminal between the first chip pad on the first surface of the first semiconductor chip and the second chip pad on the second surface of the second semiconductor chip.

11. The semiconductor device of claim 3, further comprising
a first chip bonding pad and a second chip bonding pad contacting each other between the first semiconductor chip and the second semiconductor chip;
a first chip bonding insulating layer surrounding the first chip bonding pad; and
a second chip bonding insulating layer surrounding the second chip bonding pad, the second chip bonding insulating layer contacting the first chip bonding insulating layer,
wherein the first chip bonding pad is directly connected to the first chip through via of the first semiconductor chip, and
the second chip bonding pad is directly connected to the second chip through via of the second semiconductor chip.

12. The semiconductor device of claim 2, wherein
the semiconductor chips further respectively include a conductive contact electrode extending from the peripheral circuit structure to the cell array structure,
wherein the conductive contact electrode is connected to the first contact pad and the second contact pad.

13. A semiconductor device comprising:
a package substrate; and
a first set of semiconductor chips stacked on the package substrate,
wherein each semiconductor chip of the first set of semiconductor chips respectively includes:
a first semiconductor substrate,
a first peripheral circuit structure on the first semiconductor substrate,
a first cell array structure on the first peripheral circuit structure,
a first contact pad in the first peripheral circuit structure,
a second contact pad in the first cell array structure, the second contact pad contacting the first contact pad,
a contact insulating layer on a boundary between the first peripheral circuit structure and the first cell array structure, the contact insulating layer surrounding the first contact pad and the second contact pad,
a first chip through via penetrating the first semiconductor substrate and first the peripheral circuit structure, the first chip through via being connected to the first contact pad, and
a second chip through via penetrating the first cell array structure, the second chip through via being connected to the second contact pad, and
wherein the first chip through via of a first semiconductor chip of the first set of semiconductor chips is connected to the second chip through via of a second semiconductor chip of the first set of semiconductor chips.

14. The semiconductor device of claim 13, wherein
the semiconductor device includes a second set of semiconductor chips stacked on the package substrate,
each semiconductor chip of the second set of semiconductor chips respectively includes:
a second semiconductor substrate,
a second peripheral circuit structure and a second cell array structure on substantially the same plane on the second semiconductor substrate, and
a third chip through via penetrating the second semiconductor substrate, and
the third chip through via of a third semiconductor chip of the second set of semiconductor chips is connected to the first chip through via of the first semiconductor chip and to the second chip through via of the second semiconductor chip.

15. The semiconductor device of claim 14, wherein
the first set of semiconductor chips and the second set of semiconductor chips are alternately stacked on the package substrate.

16. The semiconductor device of claim 15, further comprising:
a first chip pad connected to the first chip through via of the first semiconductor chip;
a second chip pad facing the first chip pad and connected to the third chip through via of the third semiconductor chip;
a third chip pad connected to the second chip through via of the second semiconductor chip;
a fourth chip pad facing the third chip pad and connected to the third chip through via of the third semiconductor chip; and
a chip connecting terminal between the first chip pad and the second chip pad and between the third chip pad and the fourth chip pad.

17. The semiconductor device of claim 15, further comprising:
a first chip bonding pad and a second chip bonding pad contacting each other between one of the first set of semiconductor chips and one of the second set of semiconductor chips;
a first chip bonding insulating layer surrounding the first chip bonding pad; and
a second chip bonding insulating layer surrounding the second chip bonding pad, the second chip bonding insulating layer contacting the first chip bonding insulating layer,
wherein the second chip through via of the one of the first set of semiconductor chips is directly connected to the first chip bonding pad, and
the third chip through via of the one of the second set of semiconductor chips is directly connected to the second chip bonding pad.

18. The semiconductor device of claim 14, wherein
the number of the first set of semiconductor chips is different from the number of the second set of semiconductor chips.

19. The semiconductor device of claim 18, wherein
the number of the first set of semiconductor chips is greater than the number of the second set of semiconductor chips.

20. A semiconductor device comprising:
a package substrate including a first surface and a second surface opposite to each other;
a first substrate pad and a second substrate pad respectively disposed on the first surface and the second surface of the package substrate;
an external connecting terminal on the first substrate pad;
semiconductor chips respectively including a first surface and a second surface opposite to each other, the semiconductor chips being stacked on the second surface of the package substrate;
a first chip pad and a second chip pad respectively disposed on the first surface and the second surface of each of the semiconductor chips;
a first chip connecting terminal between the first chip pad of a first semiconductor chip and the second chip pad of a second semiconductor chip;
a second chip connecting terminal between the first chip pad of a third semiconductor chip and the second substrate pad;
an underfill member between adjacent semiconductor chips and between the package substrate and the lowermost semiconductor chip from among the semiconductor chips; and
a molding member covering the package substrate and the semiconductor chips,
wherein the semiconductor chips respectively include:
a semiconductor substrate,
a peripheral circuit structure on the semiconductor substrate,
a cell array structure on the peripheral circuit structure,
a first contact pad and a second contact pad contacting each other on a boundary between the peripheral circuit structure and the cell array structure,
a contact insulating layer surrounding the first contact pad and the second contact pad,
a first chip through via penetrating the semiconductor substrate and the peripheral circuit structure, the first chip through via being connected to the first contact pad and the first chip pad, and
a second chip through via penetrating the cell array structure, the second chip through via being connected to the second contact pad and the second chip pad, and
wherein the first chip through via of a semiconductor chip of the semiconductor chips is connected to the second chip through via of another semiconductor chip of the semiconductor chips.
